(19) United States
(12) Patent Application Publication
(10) Pub. No.: US 2024/0258102 A1
(43) Pub. Date: Aug. 1, 2024

(54) SUBSTRATE PROCESSING METHOD

(71) Applicant: ASM IP Holding B.V., Almere (NL)

(72) Inventors: Jihye Yang, Ansan-si (KR); Hongsuk Kim, Yongin-si (KR); JuHyuk Park, Hwaseong-si (KR); SungHa Choi, Suwon-si (KR); SangHeon Yong, Yongin-si (KR); KiHun Kim, Yongin-si (KR)

(21) Appl. No.: 18/199,018

(22) Filed: May 18, 2023

Related U.S. Application Data
(60) Provisional application No. 63/441,516, filed on Jan. 27, 2023.
(60) Provisional application No. 63/441,540, filed on Jan. 27, 2023.
(60) Provisional application No. 63/441,557, filed on Jan. 27, 2023.

(51) Int. Cl. H01L 21/02

(52) U.S. Cl. CPC H01L 21/02274; H01L 21/02164; H01L 21/0217; H01L 21/02219; H01L 21/0223; H01L 21/02252

(57) ABSTRACT

A substrate processing method includes providing a substrate having a gap structure into a reaction space, and supplying a silicon precursor and nitrogen reactant gas into the reaction space, and depositing a flowable silicon nitride film on the substrate to fill at least a part of the gap of the substrate, while maintaining an inside of the reaction space in a plasma state by applying radio frequency (RF) power in a pulsed mode, wherein as a duty ratio of the RF power decreases, fewer micropores are generated in the silicon nitride film in the gap.

### CROSS-REFERENCE TO RELATED APPLICATIONS

This application claims priority to U.S. Provisional Patent Application Ser. No. 63/441,516 filed Jan. 27, 2023 titled SUBSTRATE PROCESSING METHOD; U.S. Provisional Patent Application Ser. No. 63/441,540 filed Jan. 27, 2023 titled SUBSTRATE PROCESSING METHOD; and U.S. Provisional Patent Application Ser. No. 63/441,557 filed Jan. 27, 2023, the disclosures of which are hereby incorporated by reference in their entirety.

### BACKGROUND

### 1. Field

The disclosure relates to a substrate processing method, and more particularly, to a method of improving the thin-film quality of a silicon oxide film.

### 2. Description of the Related Art

In a semiconductor manufacturing process, a silicon oxide film may be formed largely by using two processes. One process is a thermal oxidation process in which a silicon oxide film is formed on a substrate by heating the substrate at 800° C. to 1,200° C. in an oxygen or vapor atmosphere. In this process, oxygen is supplied to a substrate comprising a silicon and a part of the silicon is converted into an insulating material through chemical bonding between the silicon and the oxygen. The other process is a chemical vapor deposition (CVD) process in which precursor gases are supplied into a reaction chamber and a silicon oxide film is formed on a surface of a substrate through a chemical reaction between the precursor gases. In the CVD process, precursor gases that undergo a chemical reaction are supplied into a reaction chamber and a solid product generated by the reaction is formed on a substrate. Because this process uses a phase change from gas with high flowability, step coverage is excellent and throughput per unit time is high. In particular, in contrast to a thermal oxidation process, a silicon oxide film may be obtained without consuming silicon elements of a substrate.

Because a plasma enhanced CVD (PECVD) process uses thermal energy as an energy source required for a chemical reaction and also uses energy from plasma, a silicon oxide film may be formed relatively quickly even at a low temperature. While a reaction may be promoted when plasma is used as described above, an underlayer may be damaged due to ion bombardment. Also, when a flowable nitride film is deposited by using plasma in an existing PECVD process, a long plasma on-time causes a continuous reaction due to the nature of the CVD process, and thus, the formation of small oligomers is limited and unwanted polymers are formed. These problems result in the overall non-uniform thin-film quality on a pattern structure and the generation of micropores therein.

In a semiconductor manufacturing process, it is important to maintain a constant uniformity of the quality of a thin film formed on each portion of a substrate in order to increase the yield of a semiconductor device. However, when the quality of the thin film is generally non-uniform, the yield management of the device is greatly affected.

Accordingly, there is a demand for a technology to efficiently deposit a nitride film having uniform thin-film quality.

### SUMMARY

Provided is a method of depositing a silicon nitride film in which polymerization and micropore generation, which may occur when a flowable silicon nitride film is deposited, may be minimized.

Provided is a method of forming a uniform silicon oxide film in a gap.

One or more embodiments include a substrate processing method by which a gap may be filled with a gap-fill layer without generating a void in the gap during a gap-fill process in semiconductor manufacturing processes.

One or more embodiments include a substrate processing method by which a gap structure having a plurality of recesses that extend in different directions from one another is filled with a silicon nitride layer having flowability.

One or more embodiments include a substrate processing method by which a gap structure having a high aspect ratio of 1:10 or greater is filled with a silicon nitride layer having flowability.

One or more embodiments include a substrate processing method allowing a gap-fill layer having uniform film quality may be filled throughout the entire gap during a gap-fill process.

Additional aspects will be set forth in part in the description which follows and, in part, will be apparent from the description, or may be learned by practice of the presented embodiments.

According to an aspect of the disclosure, a substrate processing method includes providing a substrate having a gap structure into a reaction space, and supplying a silicon precursor and nitrogen reactant gas into the reaction space, and depositing a flowable silicon nitride film on the substrate to fill at least a part of the gap of the substrate, while maintaining an inside of the reaction space in a plasma state by applying radio frequency (RF) power in a pulsed mode, wherein, as a duty ratio of the RF power decreases, fewer micropores are generated in the silicon nitride film in the gap.

According to an example of the substrate processing method, depositing the silicon nitride film may include generating a plasma by using direct plasma treatment of directly generating a plasma on the substrate by applying RF power into the reaction space while supplying the silicon precursor, the nitrogen reactant gas, and inert gas into the reaction space.

According to another example of the substrate processing method, while the duty ratio of the RF power decreases, an intensity of the RF power may be kept constant.

According to a further example of the substrate processing method, the intensity of the RF power may range from 40 W to 100 W.

According to another example of the substrate processing method, the silicon precursor may be trimer-trisilylamine (TSA) or dimer-trisilylamine (TSA), and the nitrogen reactant gas may be NH₃.

According to another example of the substrate processing method, depositing the silicon nitride film may include depositing the silicon nitride film by using a plasma enhanced chemical vapor deposition (PECVD) process.

According to another aspect of the disclosure, a substrate processing method may include providing a substrate having a gap structure into a reaction space, supplying a silicon precursor and nitrogen reactant gas into the reaction space, and depositing a flowable silicon nitride film in a gap of the substrate while maintaining an inside of the reaction space in a plasma state by applying radio frequency (RF) power in a pulsed mode, converting the flowable silicon nitride film into a silicon oxide film, and forming a densified silicon oxide film by densifying the silicon oxide film, wherein as a duty ratio of the RF power in the deposition decreases within a certain range, uniformity of the densified silicon oxide film may increase.

According to an example of the substrate processing method, applying the RF power in the pulsed mode in the deposition may cause generation of fewer micropores in the silicon nitride film in the gap, compared to a case where the RF power is continuously applied.

According to another example of the substrate processing method, the certain range of the duty ratio of the RF power may be from 10% to 50%.

According to another example of the substrate processing method, the conversion may include converting the flowable silicon nitride film into the silicon oxide film by introducing remote oxygen (O₂) plasma to the flowable silicon nitride film.

According to another example of the substrate processing method, the RF power may have a frequency ranging from 13.56 MHz to 60 MHz.

According to another example of the substrate processing method, a pulse frequency of the RF power may range from 0 KHz to 100 KHz.

According to another example of the substrate processing method, the deposition may include depositing the flowable silicon nitride film by using a direct plasma treatment while supplying the silicon precursor, the nitrogen reactant gas, and inert gas into the reaction space.

According to another example of the substrate processing method, the silicon precursor may be at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂; dimer-trisilylamine, trimer-trisilylamine, tetramer-trisilylamine, pentamer-trisilylamine, hexamer-trisilylamine, heptamer-trisilylamine, octamer-trisilylamine, and a mixture thereof.

According to another example of the substrate processing method, the nitrogen reactant gas may be selected from at least one of NH₃, N₂, N₂O, NO₂, N₂H₂, N₂H₄, and a mixture thereof.

According to one or more embodiments, a substrate processing method includes supplying a substrate into a reaction space, the substrate comprising a first recess extending in a vertical direction and a second recess extending from the first recess in a direction different from the vertical direction, and filling the first recess and the second recess with a flowable film under a pulsed plasma atmosphere while supplying at least one gas into the reaction space, wherein generation of pores at an end portion of the second recess is suppressed by setting a duty ratio of the pulsed plasma less than 100%.

The generation of pores at the end portion of the second recess may be further suppressed by adjusting a ON pulse frequency of the pulsed plasma.

The ON pulse frequency may be in a range from about 4,000 Hz to about 10,000 Hz.

The adjusting of the ON pulse frequency of the pulsed plasma may include setting a reference ON pulse frequency that is a reference of the pulsed plasma, and setting an execution ON pulse frequency that is greater than the reference ON pulse frequency, and the generation of pores at the end portion of the second recess is suppressed while supplying the pulsed plasma having the execution ON pulse frequency.

The duty ratio may be 50% or less.

The at least one gas may include a silicon precursor and a nitrogen-containing gas.

The pulsed plasma atmosphere may be formed by applying a voltage to an electrode arranged in the reaction space.

At least one of a gas supply unit configured to supply the at least one gas and a substrate support unit configured to support the substrate may function as the electrode.

The voltage may be applied for a first time and the application of voltage may be suspended for a second time that is greater than the first time.

The voltage may have a first state and a second state for the first time, and the first state and the second state of the voltage may be repeated with a certain period during the first time.

The certain period may be in a range of about 0.1 ms to about 0.25 ms.

At least the first state of the voltage may have a radio frequency (RF).

According to one or more embodiments, a substrate processing method, in which a gap structure formed on a substrate is filled, includes supplying an oligomer silicon precursor having flowability, supplying a reactant gas having a reactivity with the oligomer silicon precursor, depositing a flowable film based on the oligomer silicon precursor and the reactant gas by generating radio frequency (RF) plasma in a reaction space, and decreasing flowability of the flowable film by setting a duty ratio of the RF plasma to be within a range of about 20% to about 40%.

The gap structure may include a first recess extending in a vertical direction toward the substrate and a second recess extending from the first recess in a horizontal direction, and a capillary condensation effect that may occur while the flowable film fills the second recess may be suppressed by the decreasing of the flowability of the flowable film.

Generation of pores at an end portion of the gap structure may be suppressed by the decrease of the flowability of the flowable film.

The generation of pores at the end portion of the gap structure may be further suppressed by setting a ON pulse frequency of the RF plasma to be in a range of about 4,000 Hz to about 6,000 Hz.

According to one or more embodiments, a substrate processing method includes loading a substrate onto a substrate support unit, the substrate including a first recess extending in a vertical direction and a second recess extending in a horizontal direction, supplying an oligomer silicon precursor and a reactant gas through a gas supply unit arranged on the substrate support unit, and generating in-situ plasma in a reaction space by applying a voltage to at least one of the substrate support unit and the gas supply unit, wherein the first recess and the second recess are filled with a flowable film by supplying the oligomer silicon precursor and the reactant gas and generating the in-situ plasma, and generating the in-situ plasma comprises a radio frequency (RF) ON-operation performed for a first time and an RF OFF-operation performed for a second time that is greater than the first time.

An RF pulse having the ON pulse frequency may be applied during the RF ON-operation.

The ON pulse frequency may be in a range from about 4,000 Hz to about 6,000 Hz.

A frequency of an RF voltage included in the RF pulse may be about 10 MHz or greater.

According to one or more embodiments, a method of filling a gap structure formed in a substrate includes supplying a source having flowability, supplying a reactant having reactivity with the source, generating radicals of at least the reactant by applying plasma via an electrode arranged in a reaction space for a first time, and suspending the applying of the plasma for a second time that is greater than the first time.

A duty ratio of the plasma may be defined as a ratio of the first time with respect to sum of the first time and the second time, and generation of pores in an end portion of the gap structure may be suppressed by setting the duty ratio under a certain value.

The radicals may move toward a bottom of the gap structure during the suspending of the applying of the plasma.

The second time and a depth of the gap structure may be proportional to each other.

During the generating of the radicals of the reactant, a first reaction for filling the gap structure may be carried out.

During the suspending of the applying of the plasma, a second reaction for filling the gap structure may be carried out.

A film filling the gap by the method may have a first part formed by the first reaction and a second part formed by the second reaction, and an amount of the second part may be greater than an amount of the first part.

The gap structure may have an aspect ratio of 1:10 or greater.

During the first time, radio frequency (RF) pulses having a ON pulse frequency less than 4 kHz may be applied.

A frequency of an RF voltage included in the RF pulse may be about 10 MHz or greater.

The method may further include generating radicals of the reactant by applying additional plasma for a third period of time that is greater than the first time.

A duty ratio of the additional plasma may be greater than a duty ratio of the plasma.

The additional plasma may be applied in a continuous plasma mode.

The source may include at least one selected from dimer-trisilylamine (TSA), trimer-TSA, tetramer-TSA, pentamer-TSA, hexamer-TSA, heptamer-TSA, and octamer-TSA, or a mixture thereof.

The reactant may be at least one selected from N₂, N₂O, NO₂, NH₃, N₂H₂, N₂H₄, and radicals thereof, or a mixture thereof.

According to one or more embodiments of the present disclosure, a substrate processing method includes providing a substrate having a gap structure having an aspect ratio of 1:10 or greater into a reaction space, and filling the gap structure with a flowable film under a radio frequency (RF) plasma atmosphere while supplying at least one gas into the reaction space, wherein a duty ratio of the RF plasma is set in a range of 20% to 40% so that generation of pores at an end portion of the gap structure is suppressed.

The generation of pores at the end portion of the gap structure may be further suppressed by setting a ON pulse frequency of the RF plasma to be in a range of about 500 Hz to about 2 kHz.

According to one or more embodiments of the present disclosure, a method of filling a gap structure formed in a substrate includes supplying a source having flowability, supplying a reactant having reactivity with the source, generating radicals of the reactant, ions of the reactant, and electrons, and removing the ions and the electrons, wherein the source reacts with the radicals during removing the ions and the electrons.

The method may further include loading the substrate onto a substrate support unit, supplying an oligomer silicon precursor and a reactant gas through a gas supply unit arranged on the substrate support unit, and generating in-situ plasma in a reaction space by applying a voltage to at least one of the substrate support unit and the gas supply unit.

The gap structure may be filled with a flowable film by the supplying of the oligomer silicon precursor and the reactant gas and the generating of the in-situ plasma, and the generating of the in-situ plasma may include a radio frequency (RF) ON-operation performed for a first time and an RF OFF-operation performed for a second time that is greater than the first time.

The RF ON-operation may be carried out during the generating of the radicals of the reactant, the ions of the reactant, and the electrons, and the RF OFF-operation may be carried out during the removing of the ions and the electrons.

### BRIEF DESCRIPTION OF THE DRAWINGS

The above and other aspects, features, and advantages of certain embodiments will be more apparent from the following description taken in conjunction with the accompanying drawings, in which:

FIG. 1 is a timing diagram schematically illustrating a process sequence of an existing substrate processing method;

FIG. 2 is a block diagram illustrating a substrate processing method, according to an embodiment;

FIG. 3 is a timing diagram schematically illustrating a process sequence of a step of depositing a silicon nitride film, according to an embodiment;

FIG. 4 is a timing diagram schematically illustrating a process sequence of a step of depositing a silicon nitride film, according to another embodiment;

FIG. 5 illustrates (a) a continuous wave of RF power supplied during a plasma supply step using a continuous mode of RF power of FIG. 1; (b) a pulsed wave of RF power supplied during a plasma supply step using a pulsed mode of RF power of FIG. 3;

FIG. 6 is a table illustrating specific process conditions for a step of depositing a silicon nitride film, according to an embodiment; and

FIG. 7 is a view illustrating transmission electron microscopy (TEM) images of silicon nitride films when radio frequency (RF) power is supplied in a continuous mode (CW) and when RF power is supplied in a pulsed mode during depositing a silicon nitride film.

FIG. 8 is a block diagram for describing a substrate processing method according to one or more embodiments of the present disclosure;

FIG. 9 is a diagram showing a molecular structure of a dimer-TSA in which two monomer-TSAs are combined;

FIG. 10 is a diagram showing a molecular structure of a trimmer-TSA in which three monomer-TSAs are bonded or a monomer-TSA and a dimer-TSA are bonded;

FIG. 11 is a diagram illustrating an example of a molecular structure reaction scheme that may be applied to a substrate processing method according to one or more embodiments of the present disclosure;

FIG. 12 is a schematic diagram for describing a continuous mode plasma used in a plasma enhanced chemical vapor deposition (PECVD) process;

FIG. 13 is a diagram schematically showing a pulse plasma with a relatively high ON pulse frequency used in a PECVD process;

FIG. 14 is an enlarged view illustrating a section ‘1’ of FIG. 13, that is, a section in which radio frequency (RF) power is turned on;

FIG. 15 is a diagram schematically showing a pulse plasma with a relatively low ON pulse frequency used in a PECVD process;

FIG. 16 is an enlarged view illustrating a section ‘1’ of FIG. 15, that is, a section in which RF power is turned on;

FIG. 17 is a schematic diagram for describing a pulse plasma method having a relatively low duty ratio and a high ON pulse frequency used in a PECVD process;

FIG. 18 is a schematic diagram for describing a pulse plasma method having a relatively low duty ratio and a low ON pulse frequency used in a PECVD process;

FIGS. 19 to 23 are cross-sectional views for describing a substrate processing method according to an embodiment of the present disclosure in a processing order;

FIG. 24 is a diagram schematically showing a substrate processing apparatus according to an embodiment of the present disclosure;

FIG. 25 is a flowchart schematically illustrating a substrate processing method using a substrate processing apparatus;

FIG. 26 is a diagram showing a gap fill characteristic of a lateral structure pattern according to a duty ratio and a ON pulse frequency in a continuous plasma and a duty plasma; and

FIG. 27 is a diagram showing gap-fill states when the processing times are short and long under the same conditions as in FIG. 16.

FIG. 28 illustrates a definition of plasma duty ratio.

FIGS. 29 to 33 are cross-sectional views for describing a substrate processing method according to an embodiment of the present disclosure in a processing order;

FIG. 34 shows a result of an experiment in which a flowable film is deposited on an HAR pattern by using continuous plasma and duty plasma; and

FIG. 35 is a diagram for defining a duty ratio of plasma.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings.

Embodiments are provided to further explain the disclosure to one of ordinary skill in the art, and the following embodiments may have different forms and the scope of the disclosure should not be construed as being limited to the descriptions set forth herein. Rather, these embodiments are provided so that the disclosure will be thorough and complete, and will fully convey the scope of the disclosure to one of ordinary skill in the art.

The terminology used herein is for describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

Embodiments will be described hereinafter with reference to the drawings in which embodiments are schematically illustrated. In the drawings, variations from the illustrated shapes may be expected because of, for example, manufacturing techniques and/or tolerances. Thus, the embodiments should not be construed as being limited to the particular shapes of regions illustrated herein but may include deviations in shapes that result, for example, from manufacturing processes.

First, a substrate processing method of forming a silicon oxide film in a gap on a substrate according to a flowable process using a plasma enhanced chemical vapor deposition (PECVD) process will be described. A substrate processing method of forming a silicon oxide film on a substrate according to an embodiment may be used to form an electronic device such as a semiconductor device.

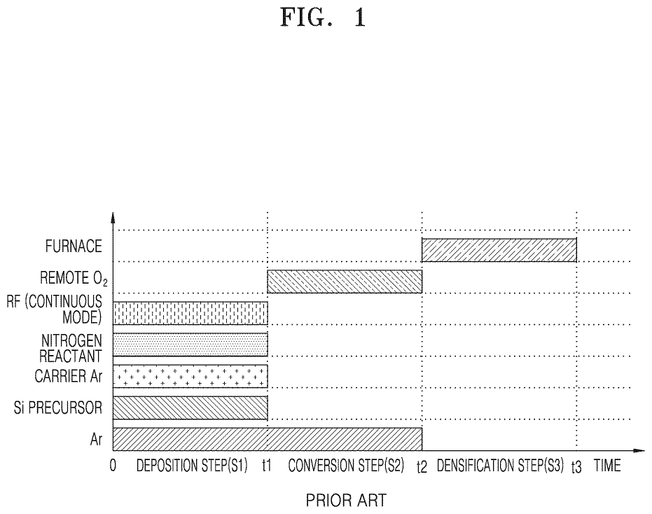

FIG. 1 is a timing diagram schematically illustrating a process sequence of an existing substrate processing method, especially illustrating a process sequence of a method of forming a silicon nitride film and then converting the silicon nitride film into a silicon oxide film.

Referring to FIG. 1, a substrate processing method according to an embodiment may include a deposition step S1 of depositing a flowable silicon nitride film, a conversion step S2 of converting the flowable silicon nitride film into a silicon oxide film, and optionally a densification step S3 of forming a densified silicon oxide film by densifying the silicon oxide film, along a horizontal axis representing time.

Referring to FIG. 1, in the deposition step S1, silicon precursor gas, nitrogen reactant gas, and inert gas (e.g., argon) that is carrier gas of the silicon precursor gas may be supplied into a reaction chamber, and a flowable silicon nitride film may be deposited on a substrate while maintaining the inside of the reaction chamber in a plasma atmosphere. For example, the deposition step S1 may be performed through a PECVD process.

The silicon precursor used in the deposition step S1 may be at least one of silicon-containing precursors such as a silicon-containing oligomer, aminosilane, idosilane, silicon hydrohalide, and silicon halide. For example, the silicon-containing precursor may be at least one selected from among TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂; and a silicon-containing oligomer with about 2 to 10 chain structures. Specific examples of the silicon-containing oligomer may include, but are not limited to, dimer-trisilylamine, trimer-trisilylamine, tetramer-trisilylamine, pentamer-trisilylamine, hexamer-trisilylamine, heptamer-trisilylamine, and octamer-trisilylamine. In another embodiment, the silicon precursor may be a silicon precursor not containing carbon, and may be at least one selected from among silane (SiH₄), disilane (Si₂H₆), trisilylamine, silicon hydrohalide, and silicon halide. The silicon precursor may be supplied alone to the reaction chamber, or two or more silicon precursors may be supplied into the reaction chamber together.

The nitrogen reactant may be, for example, nitrogen reactant gas that may provide a nitrogen component to the film. The nitrogen reactant gas may include at least one selected from among, but not limited to, NH₃, N₂, N₂O, NO₂, N₂H₂, N₂H₄, and a mixture thereof. In some embodiments, NH₃ may be used as the nitrogen reactant gas. The nitrogen reactant gas may promote condensation and cross-linking during oligomerization of the silicon precursor. Accordingly, a bonding structure of the silicon nitride film may be more complete. When a silicon nitride film is formed on the substrate having a gap structure by supplying only a silicon precursor source without supplying nitrogen reactant gas, for example, NH₃ plasma, it may be difficult to fill a gap without voids (void-free).

The silicon precursor gas and the nitrogen reactant gas may be supplied together with argon (Ar) gas that is a carrier gas into the reaction chamber. In this case, the silicon precursor gas may be transported by the argon carrier gas, and purge gas, for example, argon gas, may continuously flow in the reaction chamber.

A process temperature in the reaction chamber during the deposition step S1 may be maintained at about 0° C. to about 150° C., preferably about 40° C. to about 100° C. In order to make the inside of the reaction chamber in a plasma state, relatively low radio frequency (RF) power, for example, RF power of 0 W to about 650 W, preferably about 40 W to about 100 W may be applied. An RF frequency used in this case may range from 10 MHz to 60 MHz, preferably from about 13.56 MHz to about 60 MHz. Pressure in the reaction chamber during the deposition step S1 of depositing the silicon nitride film may be maintained at about 1.0 Torr to about 9.0 Torr.

In order to make the reaction chamber in a plasma atmosphere, in embodiments, a direct plasma treatment of directly generating a plasma on a substrate may be used by directly applying RF power to a reaction chamber while supplying silicon precursor gas and nitrogen reactant gas together into the reaction chamber. In another embodiment, plasma may be generated by exciting a reaction gas remotely outside a reactor and delivered into a reaction space or may be generated by exciting a reaction gas using another source (e.g., UV).

The inside of the reaction space may be maintained in a plasma state by suppling RF power in a continuous mode during the deposition step S1 of FIG. 1. That is, RF power may be continuously supplied during the deposition step S1. Accordingly, a certain amount of power may be applied during the deposition step S1.

The silicon precursor supplied into the reaction chamber together with the nitrogen reactant gas flows with flowability on the substrate by thermal energy supplied to the substrate in the reaction chamber of the plasma atmosphere, and a flowable silicon nitride film is formed on the substrate. In this case, in order to allow the silicon precursor to have appropriate flowability, a temperature of the substrate may be maintained at a relatively low temperature, for example, at about 150° C. or lower, for example, at a temperature between about 30° C. and about 70° C. When a monomer or a single molecular silicon precursor is supplied to the substrate that is maintained within the temperature range, the silicon precursor may easily volatilize and lose flowability. In contrast, when a high polymer silicon precursor having a complex molecular structure is supplied, the silicon precursor may not have significant flowability. Accordingly, in order to allow a silicon source to have significant flowability on the substrate and suitable for a semiconductor manufacturing process within the temperature range of the substrate, a silicon precursor having a molecular structure that is not too simple or too complex may be used. For example, the silicon precursor may be an oligomer with 2 to 10 chain structures.

In another embodiment, when the silicon precursor includes a carbon-containing group such as a methyl, ethyl, or propyl group, a carbon-containing material may be generated in a silicon nitride film forming process. Carbon may act as an impurity in the film to decrease the purity of the film or change characteristics of the film, for example, an etch rate, thereby causing device defects in a subsequent process. Accordingly, it may be preferable that as the silicon precursor, a silicon precursor having an appropriate molecular weight and not containing carbon may be used.

The silicon precursor supplied to the substrate flows on the substrate, and bonds are formed between silicon precursor molecules while the silicon precursor flows, to form a structure with about 10 chain structures, which is referred to as oligomerization. The oligomerization is promoted through condensation between the silicon precursor molecules. In the condensation, hydrogen may be removed as a reaction by-product from an Si—H bond of the silicon precursor. Oligomers combined through the condensation may flow in the flowable silicon nitride film to form a network structure through a cross-linking. Accordingly, a flowable silicon nitride film may be formed on the substrate.

However, when the inside of the reactor is maintained in a plasma state by continuously supplying RF power during the deposition step S1 as shown in FIG. 1, a reaction between molecules may continuously occur, and thus, the formation of small oligomers may be limited and unwanted polymers may be generated. Also, when plasma, in particular, direct plasma is used during the deposition step S1, ion bombardment may occur during the deposition step S1, thereby damaging an underlayer (e.g. pattern structure). These problems result in the overall non-uniform thin-film quality of a pattern structure and the generation of micropores.

The generation of micropores results in non-uniformity of the gap-fill film, and such non-uniformity of the gap-fill film may cause various problems in subsequent processes. For example, in a process of partially etching the gap-fill layer, it may be difficult to etch the gap-fill layer to a desired target thickness due to non-uniformity in the density of the gap-fill layer. For example, in the case of a gap fill layer in which polymer is formed on its upper part and micropores are formed on its lower part, the upper part of the gap fill film may have a high density, while the lower part of the gap fill film may have a low density. When the partial etching process of the gap-fill layer proceeds at the first etching rate, etching by a thickness smaller than the target thickness may occur due to the high density of the polymer in the upper part. Conversely, when the partial etching process of the gap-fill layer proceeds at a second etching rate higher than the first etching rate, a problem of etching by a thickness greater than the target thickness may occur due to the low density of the micropores in the lower part. As a result, a gap-fill layer with a non-uniform density having polymer and/or micropores has a problem in that it has unsuitable etch properties compared to that of a gap-fill layer with a uniform density.

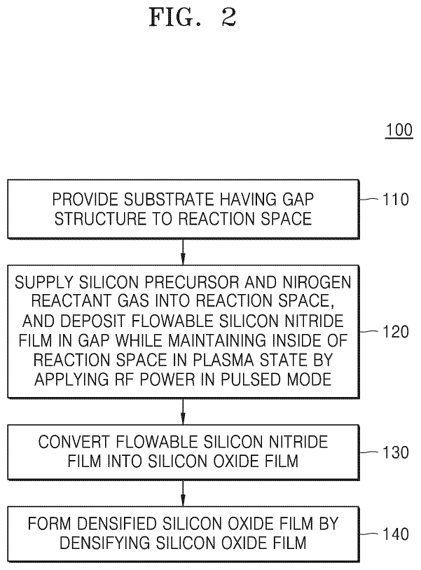

Accordingly, it is an important technical task to maintain a uniform thin-film quality over an entire structure in a subsequent process by minimizing these problems when a nitride film is deposited by using plasma. Examples for solving these technical problems will be described with reference to FIGS. 2 to 7.

Referring back to FIG. 1, in order to promote the oligomerization of the silicon nitride film and suppress the formation of pores in the silicon nitride film, not only the silicon precursor and the nitrogen reactant may be supplied but also the supply of the nitrogen reactant with respect to the silicon precursor may be sufficiently made. For example, the silicon precursor and the nitrogen reactant may be supplied so that a ratio of Si atoms to N atoms in the silicon nitride film may be 1:1 or more (1:≥1).

After the deposition step S1, the conversion step S2 of converting the flowable silicon nitride film formed on the substrate into a silicon oxide film may be performed.

The conversion step S2 may include converting the flowable silicon nitride film into a silicon oxide film by introducing remote O₂ plasma to the flowable silicon nitride film. The remote O₂ plasma used in the conversion step S2 may be formed by applying an RF having power of 0 W to 5,000 W, for example, 1,000 W to 4,000 W, specifically, about 2,000 W to about 2,500 W and a frequency of 10 MHz to 60 MHZ, for example, about 13.56 MHz to about 30 MHz in a remote plasma discharge chamber located at a remote position from the reaction chamber. Next, the remote O₂ plasma may be introduced into the reaction chamber through a connection pipe. Pressure in the reaction chamber during the conversion step S2 may be maintained in a range of about 1.0 Torr to about 9.0 Torr, preferably about 2.0 Torr to about 3.0 Torr. In this case, in order to allow the flowable silicon nitride film to be effectively converted into a silicon oxide film, a temperature of the substrate may be maintained at a temperature of about 0° C. to about 300° C., preferably about 50° C. to about 200° C. or about 50° C. to about 150° C.

In an additional embodiment, the densification step S3 may be performed on the silicon oxide film formed on the substrate after the conversion step S2. The silicon oxide film may be densified through the densification step S3 and may be hardened. The densification step S3 may include forming a densified silicon oxide film by performing rapid heat treatment on the silicon oxide film while supplying oxygen gas of 0 sccm to 5,000 sccm. Process conditions during the rapid heat treatment may include a pressure of about 1.0 Torr to about 20.0 Torr, preferably about 5.0 Torr to about 10.0 Torr, and a temperature of about 50° C. to about 650° C., preferably about 300° C. to about 550° C. or about 500° C. to about 550° C. A surface of the silicon oxide film may be densified through the densification step S3, to prevent external impurities such as carbon or nitrogen from penetrating into the silicon oxide film. In an embodiment, the densification step S3 may be performed by transporting the substrate from the deposition chamber to a separate device. For example, the densification step S3 may be performed in a furnace device or a rapid thermal processing (RTP) or rapid thermal annealing (RTA) device. For example, after the flowable silicon nitride film is formed on the substrate in the reaction chamber and is converted into the silicon oxide film, a densification process may be performed by transporting the substrate to a heat treatment chamber. In another alternative embodiment, the film formation, the film conversion, and the densification step S3 may be continuously performed in one reaction chamber.

Although not shown in detail, a purge step may be included between the deposition step S1 and the conversion step S2 or between the conversion step S2 and the densification step S3, and in the purge step, an excess silicon precursor or nitrogen reactant, or reaction by-products remaining after the deposition step S1 may be removed. Although the silicon precursor or the nitrogen reactant may be continuously supplied in the deposition step S1, the silicon precursor or the nitrogen reactant may be intermittently supplied. In this case, the purge step may be performed in a section where the silicon precursor or the nitrogen reactant is not supplied.

FIG. 2 is a block diagram illustrating a substrate processing method 100, according to an embodiment. The existing technology of FIG. 1 and embodiments of FIG. 2 may be partially the same, and thus, a repeated description will be omitted.

Referring to FIG. 2, the substrate processing method 100 includes a step 110 of providing a substrate having a gap structure into a reaction space. A reaction chamber that provides the reaction space may be a reaction chamber in which, for example, a semiconductor manufacturing process may be performed. The reaction chamber may be a direct plasma reaction chamber in which plasma may be directly generated near a top surface of the substrate. Alternatively, the reaction chamber may be a remote plasma reaction chamber including a remote plasma discharge chamber located at a remote position from the reaction chamber and a pipe for connecting the reaction chamber to the remote plasma discharge chamber.

The substrate may refer to a layer including a material on which a device, a circuit, or a film may be formed. The substrate may include a bulk material such as silicon (e.g., single crystal silicon), another group IV material such as germanium, or a compound semiconductor material such as a group III-V or II-VI semiconductor, and may include at least one layer located over or under the bulk material. Also, the substrate may include various topologies formed on its surface, for example, various types of recess regions such as those referred to as gaps.

In detail, the substrate may include a semiconductor material such as Si or Ge or various compound semiconductor materials such as SiGe, SiC, GaAs, InAs, and InP, and may include various substrates used in a semiconductor apparatus, a display apparatus, etc. such as silicon on insulator (SOI) and silicon on sapphire (SOS).

In some embodiments, the substrate may refer to only a substrate, or a substrate having various surface structures before a film according to the disclosure, for example, a flowable silicon nitride film or a silicon oxide film, is formed.

A gap used in the disclosure refers to a gap in the broadest sense, and may refer to a certain space whose upper portion is at least exposed by a surrounding structure defining the gap. For example, the gap may be a recess region of any of various geometric shapes formed in a surface of the substrate as well as a shallow trench isolation (STI) generally used in a device isolation field to define an active area in a semiconductor manufacturing process. Also, the gap may be in the form of a via passing through a conductive layer located between insulating layers or passing through an insulating layer located between conductive layers. Also, the gap may be formed by partially etching and removing a single or multi-layered specific material layer formed in the surface of the substrate. The material layer may include, for example, a conductive material, an insulating material, or a semiconductor material. Also, although the gap may have a cylindrical shape, a cross-sectional shape of a surface of the gap may be an elliptical shape or any of various polygonal shapes such as a triangular shape, a quadrangular shape, or a pentagonal shape. Also, although the gap may have an island shape having any of various surface cross-sectional shapes, the gap may have a linear shape on the substrate. Also, the gap may have a vertical profile with substantially the same width from an upper portion that is an inlet portion to a lower portion, or may have a non-vertical profile whose horizontal width increases or decreases linearly or stepwise from the upper portion to the lower portion.

Referring back to FIG. 2, there may be performed a step 120 in which a silicon precursor and nitrogen reactant gas may be supplied into the reaction space, and a flowable silicon nitride film is deposited in the gap of the substrate while maintaining the inside of the reaction space in a plasma state by applying RF power in a pulsed mode.

In more detail, an oligomer silicon precursor and nitrogen reactant gas may be supplied to the substrate through a gas supply unit facing a substrate support unit. In an embodiment, direct plasma may be generated in the reaction space by applying a voltage to at least one of the substrate support unit and the gas supply unit.

As described above, it is preferable that in order to allow the silicon precursor to have significant flowability on the substrate and be suitable for a semiconductor manufacturing process, the silicon precursor having a molecular structure that is not too simple or too complex is used. For example, the silicon precursor may be at least one of silicon-containing precursors such as aminosilane, idosilane, silicon hydrohalide, silicon halide, and a silicon-containing oligomer, or a mixture thereof. Specific examples of the silicon-containing oligomer may include, but are not limited to, dimer-trisilylamine, trimer-trisilylamine, tetramer-trisilylamine, pentamer-trisilylamine, hexamer-trisilylamine, heptamer-trisilylamine, and octamer-trisilylamine.

Also, when the silicon precursor includes a carbon-containing group, a carbon-containing material may be generated in a silicon nitride film forming process, Accordingly, it is preferable that the silicon precursor not containing carbon is used. For example, the silicon precursor may be at least one selected from among silane (SiH₄), disilane (Si₂H₆), trisilylamine, silicon hydrohalide, and silicon halide which do not contain carbon. The silicon precursor may be supplied alone to the reaction chamber or two or more silicon precursors may be supplied together to the reaction chamber. The nitrogen reactant gas may include at least one selected from among, for example, NH₃, N₂, N₂O, NO₂, N₂H₂, N₂H₄, and a mixture thereof. In an embodiment, NH₃ gas may be used as the nitrogen reactant gas.

The silicon precursor and the nitrogen reactant gas may be supplied together with argon gas that is a carrier gas into the reaction chamber. In this case, the silicon precursor gas may be transported by the argon carrier gas, and purge gas, for example, argon gas, may continuously flow in the reaction chamber.

The film refers to a layer that continuously extends in a direction perpendicular to a thickness direction without substantially a pinhole to cover an entire target or a surface of interest, or simply a layer that covers a target or a surface of interest. In some embodiments, a layer refers to a structure having a specific thickness formed on a surface, or refers to a film or a structure that is not a film. A film or a layer may be constituted by a discrete single film or layer having certain characteristics or multiple films or layers, and a boundary between adjacent films or layers may or may not be clear and may or may not be established based on physical, chemical, and/or any another characteristics, formation processes or sequences, and/or functions or purposes of the adjacent films or layers. For example, a surface of the substrate may be a flat surface parallel to a horizontal plane, or a surface inclined at a certain angle with respect to the horizontal plane. Also, a surface of the substrate may be a convex or concave surface with respect to the horizontal plane.

When RF power is applied while supplying the silicon precursor and the reactant gas into the reaction space, the reaction space may be in a plasma state and a flowable silicon nitride film may be deposited on an exposed surface of the substrate including the gap through condensation, oligomerization, and polymerization between the silicon precursor and the reactant gas.

A flow direction of the silicon nitride film may be closely related to a direction of a force applied to the silicon nitride film. For example, when gravity is applied to the silicon nitride film, a flow direction of the silicon nitride film is a direction in which the gravity is applied. Accordingly, when a surface of the substrate is a convex surface, the silicon nitride film may be formed while flowing from a convex portion toward a circumference thereof. In contrast, when a surface of the substrate is a concave surface recessed from a horizontal plane, the flowable silicon nitride film may be formed while flowing toward a concave portion. A case where a surface of the substrate is concave in a process of manufacturing a semiconductor device may include, for example, a gap structure, a via structure, and a stepped structure.

In the present embodiment, the flowable silicon nitride film may flow down from an upper portion of the gap to a lower portion of the gap due to flowability, and thus, may fill at least a part of the gap. As the deposition step is further performed, the inside of the gap may be completely filled with the flowable silicon nitride film without generating voids.

When compared to the deposition step S1 of depositing the flowable silicon nitride film of the existing substrate processing method of FIG. 1, the deposition step 120 of depositing the flowable silicon nitride film according to the disclosure of FIG. 2 is different in that RF power is applied in a pulsed mode.

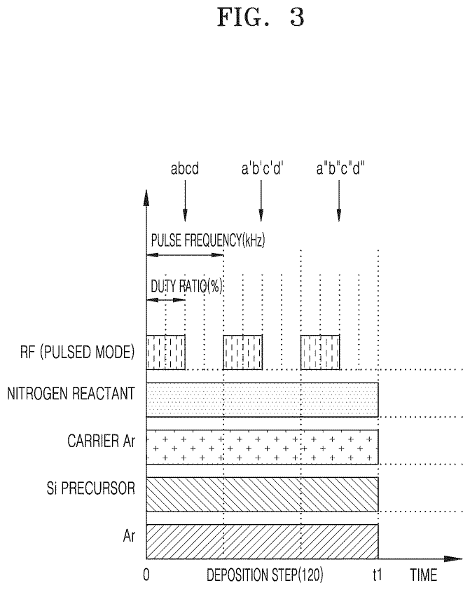

As such, according to embodiments of FIG. 2, RF power is intermittently applied in a pulsed mode, without being continuously applied as shown in FIG. 1. In detail, RF power may be intermittently supplied over a plurality of sub-periods of the deposition step 120, and RF power may be applied at a duty ratio of less than 100% (e.g., a duty ratio of less than 50%) during each sub-period. The duty ratio refers to a time for which a pulse is actually applied with respect to a pulse period. A method of applying RF power in a pulsed mode will be described with reference to FIGS. 3 to 5.

As described above, when the silicon nitride film is deposited by using a plasma, a reaction may be promoted and the film may be relatively rapidly deposited, but an underlayer such as a pattern structure may be damaged due to ion bombardment. Also, when RF power is applied in a continuous mode as shown in FIG. 1, polymerization may occur due to excessive plasma. These problems may occur, particularly, when a gap-fill process is performed by using a direct plasma method of generating a plasma on a substrate, and may cause process problems. For example, when a step (e.g., the conversion step S2 of FIG. 1) of converting the silicon nitride film into a silicon oxide film is performed as a post-treatment process, the silicon nitride film may not be effectively and uniformly converted into the silicon oxide film due to polymerization.

However, when RF power is applied in a pulsed mode, compared to a case where RF power is continuously applied, damage to an underlayer due to ion bombardment may be reduced, and plasma effect may be reduced, thereby preventing polymerization. As a result, the silicon nitride film having uniform film quality may be deposited in the gap. Also, conversion from the silicon nitride film to a silicon oxide film may be uniformly performed. In particular, as a duty ratio of RF power of the deposition step decreases within a certain range, conversion from the silicon nitride film to a silicon oxide film may be effectively and uniformly performed, and thus, the uniformity of the silicon oxide film formed in steps 130 and 140 described below may be improved.

Referring back to FIG. 2, a step 130 of converting the flowable silicon nitride film into a silicon oxide film may be performed.

For example, the conversion step 130 may be performed through plasma treatment on the silicon nitride film. In an embodiment, while plasma is directly applied in the deposition step 120, oxygen gas may be remotely activated and supplied in the conversion step 130. Also, plasma treatment in the conversion step 130 may be performed by ex-situ plasma treatment. That is, the deposition step 120 may be performed by direct (in-situ) plasma treatment of directly generating a plasma on the substrate, whereas the conversion step 130 may be performed by remote (ex-situ) plasma treatment of supplying oxygen plasma to the substrate through a delivery pipe.

In an embodiment, the conversion step 130 may be performed at a relatively high temperature. For example, the conversion step 130 may be performed at a temperature higher than that of the deposition step 120.

The silicon oxide film formed through the conversion step 130 may entirely have uniform film quality. The uniform film quality of the silicon oxide film may result from the step 120 of depositing the silicon nitride film by applying RF power in a pulsed mode. In more detail, this is because polymerization during the deposition of the silicon nitride film may be prevented due to RF power in a pulsed mode, and thus, conversion from the silicon nitride film into the silicon oxide film may be effectively and uniformly performed.

In an additional embodiment, after the conversion step 130, a step 140 of forming a densified silicon oxide film by densifying the silicon oxide film may be performed.

The densification may be performed by using any of various methods such as plasma treatment, UV treatment, E-beam (electron beam), or rapid thermal processing (RTP). The densification may be performed under an oxygen atmosphere, and may be performed at a relatively high temperature. For example, the densification step 140 may be performed at a temperature higher than that of the deposition step 120 and/or the conversion step 130.

A surface of the silicon oxide film may be densified and hardened through the densification step 140, to prevent external impurities such as carbon or nitrogen from penetrating into the silicon oxide film.

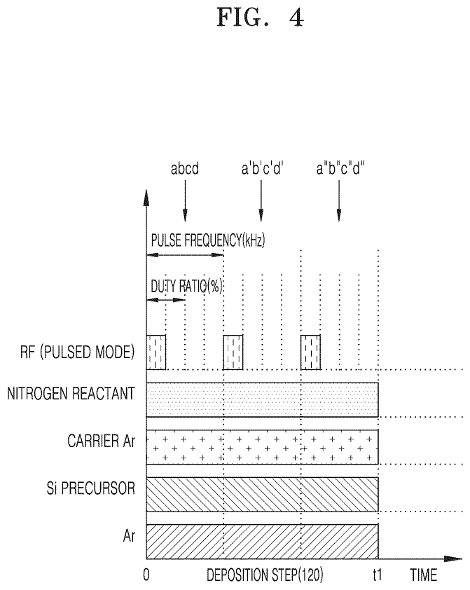

FIGS. 3 and 4 are timing diagrams schematically illustrating a process sequence of a step of depositing a silicon nitride film, according to another embodiment.

In FIGS. 3 and 4, embodiments in which from among parameters, only a duty ratio is adjusted and the remaining conditions are maintained will be described. It will be understood that these embodiments are merely examples, and additional process parameters in addition to the duty ratio may be adjusted.

In FIGS. 3 and 4, unlike the deposition step S1 of FIG. 1 of continuously supplying RF power, the deposition step 120 (see FIG. 2) including a pulsed plasma supply step in which RF power is intermittently supplied is illustrated. In the embodiments of FIGS. 3 and 4, RF power may be intermittently supplied over a plurality of sub-periods, and RF power may be applied at a duty ratio of less than 100% (e.g., at a duty ratio of 10% to 50%) during each sub-period. The duty ratio refers to a time for which a pulse is applied with respect to an entire plasma generation time (in this case, 0 to t).

Referring to FIGS. 3 and 4, a sub-period may be repeated for a period of 0 to t. Although a sub-period is repeated three times as abcd, a′b′c′d′, and a″b″c″d″ for a period of 0 to t, and thus, a period of 0 to t includes a total of 12 individual periods in FIGS. 3 and 4, the number of times a sub-period is repeated is not limited thereto. Also, although widths of sub-periods and/or individual periods are the same, in another embodiment, widths of the sub-periods and/or individual periods may be different from each other.

In a continuous mode of FIG. 1, RF power is continuously supplied over entire sub-periods of 0 to t, whereas in a pulsed mode of FIG. 3, RF power is supplied only in individual periods ab, a′b′, and a″b″ from among sub-periods abcd, a′b′c′d′, and a″b″c″d″. Because RF power is supplied over 50% of each sub-period, a duty ratio in FIG. 3 is 50%. Likewise, in a pulsed mode of FIG. 4, RF power is supplied only in individual areas a, a′, and a″ from among sub-periods abcd, a′b′c′d′, and a″b″c″d″. Because RF power is supplied over 25% of each sub-period, a duty ratio in FIG. 4 is 25%.

In this case, for example, RF power may range from 0 W to 650 W. As described above, from among process parameters, only a duty ratio may be adjusted and the remaining conditions may be maintained. Accordingly, because a duty ratio of RF power is reduced, total RF power supplied during the deposition step 120 may be reduced. As total RF power is reduced, polymerization caused by excessive plasma may be reduced.

A pulse frequency corresponds to a frequency in a sub-period, and may range from, example, 0 kHz to 100 kHz, preferably from 10 KHz to 50 KHz.

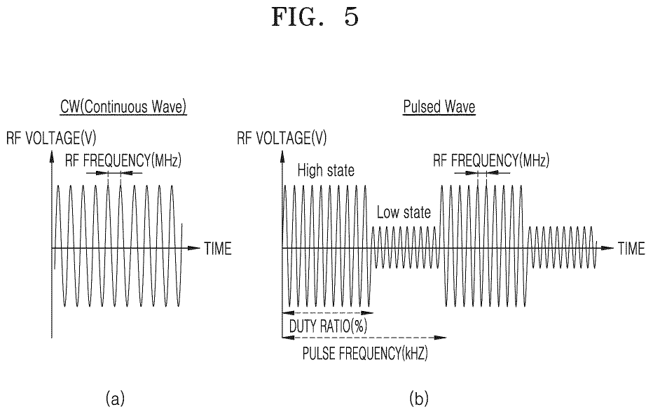

A pulsed wave of RF power supplied in a pulsed mode in FIGS. 3 and 4 is illustrated in FIG. 5. In detail, FIG. 5 (a) illustrates a continuous wave of RF power supplied during a plasma supply step of a continuous mode of FIG. 1. FIG. 5 (b) illustrates a pulsed wave of RF power supplied during a plasma supply step of a pulsed mode of FIG. 3.

As shown in FIG. 5, RF power may be provided as an alternating wave, and an RF frequency may range from, for example, 13.56 MHz to 60 MHz.

In FIG. 5 (b), a high state of an RF voltage causes a plasma-on state, and a low state causes a plasma-off state. Accordingly, when an RF voltage is applied as a pulsed wave as shown in FIG. 5 (b), an on state and an off state may be repeated at a certain pulse period and plasma may be applied, thereby preventing a continuous reaction.

A pulse frequency of a pulsed wave may range from, example, 0 kHz to 100 kHz, preferably from 10 kHz to 50 KHz.

A duty ratio refers to a proportion of a high state in a pulse period. Referring to FIG. 5 (b), it is found that a pulsed wave has a duty ratio of 50%. In another example, a duty ratio may range from, for example, 10% to 90%, preferably from 10% to 50%.

### EMBODIMENTS

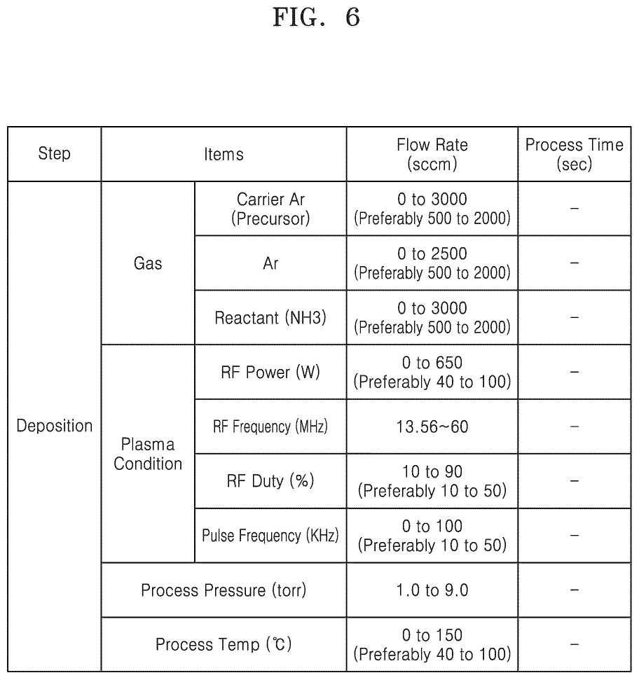

A step of depositing a silicon nitride film according to embodiments was performed according to a process described with reference to FIGS. 2 to 4. A silicon-containing oligomer, for example, trisilylamine-based oligomer precursor, was used as a silicon precursor source, and NH₃ gas was used as nitrogen reactant gas. FIG. 6 illustrates specific process conditions of a step of forming a silicon nitride film, according to the present embodiment.

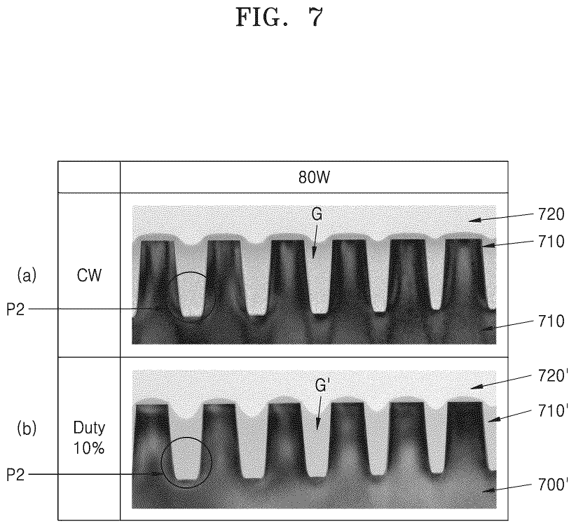

Transmission electron microscopy (TEM) analysis was performed on a flowable silicon nitride film obtained by performing a method of FIG. 2 while satisfying process conditions of FIG. 6 (FIG. 7), and the degree of micropore generation in a nitride film pattern was compared between a case where RF power was supplied in a continuous mode CW and a case where when RF power was supplied in a pulsed mode.

FIG. 7 illustrates TEM images of silicon nitride films for observing the degree of micropore generation when RF power is supplied in a continuous mode CW and when RF power is supplied in a pulsed mode having a duty ratio of 10% during depositing a silicon nitride film. FIG. 7A is a TEM cross-sectional image of a silicon nitride film deposited while supplying RF power of 80 W and 27 MHz in a continuous mode CW. FIG. 7B is a TEM cross-sectional image of a silicon nitride film deposited while applying RF power of 80 W and 27 MHz in a pulsed mode having a duty ratio of 10%.

When the TEM images of FIGS. 7A and 7B are compared with each other, silicon nitride films 710 and 710′ are formed on substrates 700 and 700′ having gap structures G and G′. Reference numerals 720 and 720′ denote background spaces. It is found from FIG. 7 that the number of micropores P2 generated when RF power with a specific intensity (in this case, 80 W) is applied in a pulsed mode (in this case, a duty ratio of 10%) (FIG. 7B) is less than the number of micropores P1 generated when RF power with the same intensity is supplied in a continuous mode CW (FIG. 7A). That is, it is found that assuming that RF power with the same intensity is supplied, fewer micropores are generated in a silicon nitride film when the RF power is supplied in a pulsed mode rather than in a continuous mode CW. This is because when RF power is applied in a pulsed mode during depositing a flowable silicon nitride film, a continuous reaction may be prevented, and thus, the formation of unwanted polymers may be prevented and the formation of small oligomers may be promoted.

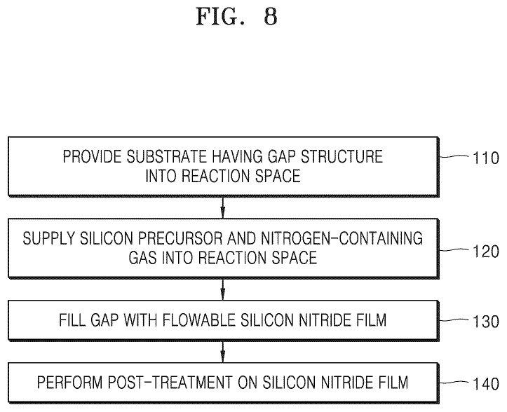

FIG. 8 is a block diagram showing an example of a substrate processing method according to one or more embodiments of the present disclosure.

Referring to FIG. 8, a substrate is provided in a reaction space 110. A reaction space may be, for example, a reaction chamber in which semiconductor manufacturing processes may be performed. The substrate may include various substrates having a surface on which a flowable silicon nitride film may be formed according to one or more embodiments of the present disclosure. The surface of the substrate, on which the silicon nitride film may be formed, may include a single material, for example, a conductive material, an insulating material, a semiconductor material, etc., or two or more different materials. In addition, the substrate may have various surface geometries on which the silicon nitride film may be formed. For example, the surface of the substrate may be a flat surface that is parallel to a horizontal plane or a surface inclined at a certain angle with respect to the horizontal plane. Also, the surface of the substrate may be convex or concave with respect to the horizontal plane.

As described later, the silicon nitride film formed on the substrate has flowability, and a flowing direction of the silicon nitride film may be closely dependent on a direction of force applied to the silicon nitride film. For example, when the gravity applies to the silicon nitride film, the flowing direction of the silicon nitride film is a direction in which the gravity applies. Thus, when the surface of the substrate is convex, the silicon nitride film may be formed while flowing from the convex portion toward the periphery. On the contrary, when the surface of the substrate is concave recessed from the horizontal plane, the silicon nitride film having flowability may be formed while flowing toward the concave portion. An example in which the surface of the substrate is concave may include, for example, a gap structure, a via structure, or a stepped structure during the manufacturing processes of the semiconductor device.

The substrate provided during operation 110 may have a gap structure. It should be noted that the gap structure is not limited to a gap structure of a general meaning formed on a surface of the semiconductor device. That is, the substrate to which one or more embodiments may be applied may denote a structure having various types of recessed regions or concave regions in which the silicon nitride film may be intensively filled while flowing under the influence of the gravity when the silicon nitride film having flowability is formed on the substrate. In detail, a structure with a recess region or concave region may include, for example, a general gap structure such as a shallow trench isolation (STI) in the manufacturing processes of a semiconductor device, a via structure penetrating through an insulating layer to connect a conductive layer to another conductive layer in a structure of conductive layer/insulating layer/conductive layer, a via structure penetrating through the conductive layer to connect the insulating layer to another insulating layer in a structure of insulating layer/conductive layer/insulating layer, and a stepped structure having a stair shape from the surface in a depth direction, etc. Hereinafter, descriptions are provided to the one or more embodiments of the present disclosure applied to a substrate having a gap structure, representing a structure having a recess region or a concave region.

Referring to FIG. 8, a silicon precursor and a nitrogen-containing gas are supplied into a reaction space in which the substrate is provided 120. When a molecular structure of the supplied silicon source is too simple, for example, in the case of a monomer or a single molecule, vapor pressure is remarkably high, and thus the source is easily volatilized and flowability is lost. On the other hand, when the silicon source has a complex molecular structure, that is, a polymer, the flowability of the silicon source is too slow because of a large molecular weight and low vapor pressure, and thus, efficiency degrades in a process requiring the flowability of an appropriate level or greater. For example, when a flowable film that is used to fill a gap does not have a sufficient flowability, a void may be generated in the gap. Accordingly, the silicon precursor used in one or more embodiments of the present disclosure may have a molecular structure that is not too simple or not too complicated, for example, a low-polymer (oligomer) silicon source having about two to about ten chain structures. Examples of oligomer silicon sources may include dimer-trisilylamine (TSA), trimer-TSA, tetramer-TSA, pentamer-TSA, hexamer-TSA, heptamer-TSA, octamer-TSA, etc.

In some embodiments, each of the oligomer silicon sources may be supplied solely to the reaction space, for example, dimer-TSA may be supplied solely as a silicon precursor source, and in another embodiment, trimmer-TSA may be supplied solely as a silicon precursor source. Also, in one or more embodiments, two or more kinds of silicon precursor sources may be supplied along with each other. For example, in one or more embodiments, dimer-TSA and trimmer-TSA may be simultaneously supplied as the silicon precursor source, in one or more other embodiments, trimer-TSA and tetramer-TSA may be simultaneously supplied as the silicon precursor source, and in one or more other embodiments, dimer-TSA, trimmer-TSA, and tetramer-TSA may be simultaneously supplied as the silicon precursor source.

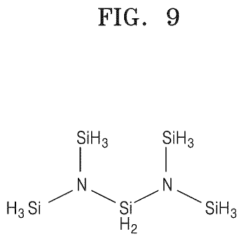

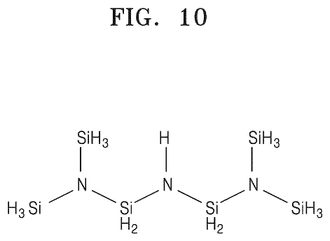

FIG. 9 shows a molecular structure of dimer-TSA in which two monomer-TSAs are combined, and FIG. 10 shows a molecular structure in which three monomer-TSAs are combined or monomer-TSA and dimer-TSA are combined.

In addition, the nitrogen-containing gas used in one or more embodiments of the present disclosure may use at least one selected from N₂, N₂O, NO₂, NH₃, N₂H₂, N₂H₄, radicals thereof, and a mixture thereof. In one or more embodiments, NH₃ may be used as the nitrogen-containing gas. The nitrogen-containing gas may function to promote a condensation reaction and cross-linking during the process of oligomerization of the oligomer silicon precursor.

Referring to FIG. 8, a silicon nitride film having flowability is formed on the substrate 130. A temperature of the substrate in the reaction space may be maintained at, for example, about 100° C. or less, for example, about 30° C. to about 70° C. Alternatively, a temperature of a container of the silicon precursor source and a temperature of silicon precursor source transfer line may be maintained at about 100° C. or less, for example, about 30° C. to about 70° C. In addition, a radio frequency (RF) power of about 100 W to about 500 W, for example, about 200 W to about 400 W, is applied to the reaction space to generate plasma in the reaction space. The RF power is a reference when a voltage is applied at a duty ratio of 100%, and the duty ratio may be changed during the process, as described later.

The RF frequency used in the RF power application may be about 13 MHz to about 60 MHz, for example, about 20 MHz to about 30 MHz. In order to generate plasma in the reaction space, in one or more embodiments of the present disclosure, the RF power is directly applied to the reaction space while supplying the silicon precursor source and the nitrogen-containing gas into the reaction space, and the plasma is generated on the substrate, that is, an in-situ plasma treatment may be carried out.

The oligomer silicon precursor supplied into the reaction space along with the nitrogen-containing gas flows with the flowability on the substrate due to thermal energy supplied to the substrate via a heating block on which the substrate is mounted in the plasma-state reaction space, and accordingly, the silicon nitride film having flowability may be formed on the substrate. Here, in order for the silicon source to have the appropriate flowability, the temperature of the substrate needs to be maintained at a relatively low temperature, for example, about 100° C. or less, for example, about 30° C. to about 70° C. As described above, when the silicon precursor source of monomer or single molecule is supplied to the substrate that is maintained within the above temperature range, the silicon precursor source is easily volatile and loses its flowability. On the other hand, when a polymer silicon precursor source having complex molecular structure is supplied, the silicon precursor source may not have significant flowability. Therefore, in the above temperature range of the substrate, an oligomer silicon precursor source having a molecular structure that is not too simple or not too complicated, for example, about two to about ten chain structures may be supplied, so that the silicon source may have the flowability that is significant and suitable for the semiconductor manufacturing processes on the substrate.

The oligomer silicon precursor source supplied to the substrate may flow on the substrate, and the oligomer precursor source molecules are bonded during flowing to form the structure having about ten chain structures. The above process is referred to as an oligomerization. The oligomerization is promoted by condensation between the oligomer source molecules. During the condensation, hydrogen may be removed as a reaction by-product from Si—H bonds of the silicon precursor source. The oligomers bonded through the condensation may have the flowability and may form a cross-linking structure through the cross-linking while flowing in the silicon nitride film.

Next, a post-treatment may be performed on the silicon nitride film formed on the substrate 140. The post-treatment may include densification on a surface of the silicon nitride film. In another embodiment, the post-treatment may include transformation of the silicon nitride film into a silicon oxide film. In another embodiment, the post-treatment may further include densification of the silicon oxide film transformed from the silicon nitride film.

The post-treatment may be performed in various ways, for example, a plasma treatment, an ultraviolet (UV) treatment, a rapid thermal process (RTP), etc. When the post-treatment is selectively performed as the plasma treatment, the plasma treatment may be performed in the in-situ plasma treatment type, in which the plasma is generated on the substrate while supplying a helium or argon gas.

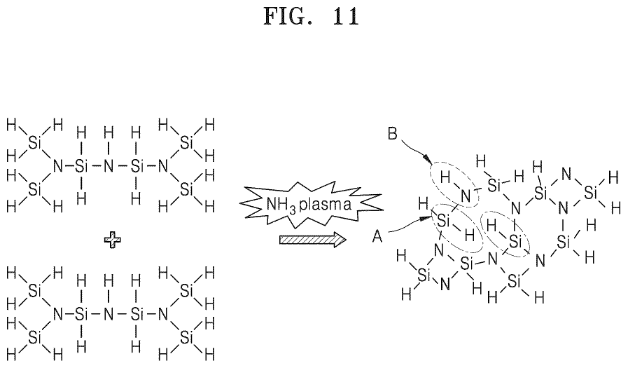

FIG. 11 is a diagram illustrating an example of a molecular structure reaction scheme that may be applied to a substrate processing method according to one or more embodiments of the present disclosure. That is, FIG. 11 shows processes in which trimmer-TSA supplied as a silicon precursor source flows along the surface of the substrate, and two trimmer-TSAs form the silicon nitride film of the cross-linking structure through the condensation and cross-linking under NH₃ plasma atmosphere.

In addition, as described above, the nitrogen-containing gas used in one or more embodiments of the present disclosure may use at least one selected from N₂, N₂O, NO₂, NH₃, N₂H₂, N₂H₄, radicals thereof, and a mixture thereof. The nitrogen-containing gas may promote the cross-linking in the oligomerization process.

In the silicon nitride film structure of the cross-linking structure shown at the right side of FIG. 11, there may be Si—H dangling bonds (e.g., a part denoted by A in FIG. 11) in the cross-linking structure formed of Si—N chain bonds, or for example, there may be N—H dangling bonds as denoted by part B of FIG. 11 in the Si—N cross-linking structure. In this case, pores may be formed in the cross-linking structure.

Due to the pores, the bonding structure of the silicon nitride film may be incomplete. In other words, when the condensation and the cross-linking are not sufficiently performed, the pores may be formed, and thus, forming of high-quality silicon nitride film may be hindered.

Such a pore formation may generate an issue in a gap-fill process of a gap structure such as a recess or a trench having a narrow width of 20 nm or less. A deep portion of a gap (that is, lower region) may be relatively less affected by the plasma, and thus, it is likely to form the pores.

In detail, when the flowable film gap-fill process is performed, the film has flowability like a liquid, and thus, a capillary condensation may occur in a narrower place. Such a capillary condensation increases the gap-fill rate, but may affect the gap-fill state of a pattern in which deposited thin films are connected in a narrow place (that is, a pattern formed subsequently). Moreover, the thin film formed in the narrow space due to the capillary condensation may be affected by subsequent plasma.

The present inventor recognized the capillary condensation occurring in the recess having the narrow width (vertical and horizontal directions), and discovered that adjusting the capillary condensation rate is an important factor in adjusting the gap-fill state of the flowable film. The present inventor tried to adjust the capillary condensation by adjusting the duty ratio and a ON pulse frequency in a structure in which a lateral pattern and a trench pattern are mixed, such as a gap structure having the narrow recess and a gate all around (GAA) structure.

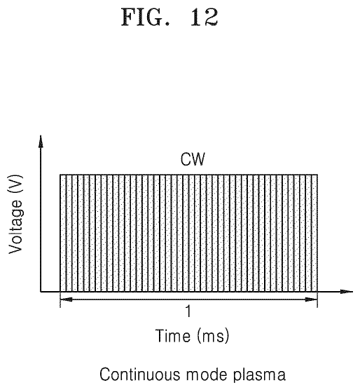

FIG. 12 is a schematic diagram for describing a continuous mode plasma used in a plasma enhanced chemical vapor deposition (PECVD) process. Referring to FIG. 12, in a continuous plasma method, an RF voltage applied to the reaction chamber is maintained at a certain value without being stopped. In FIG. 12, section ‘1’ represents a section in which RF power is turned on. As the continuous plasma is applied into the reaction chamber, the process may be performed under a relatively stabilized plasma atmosphere in the reaction chamber.

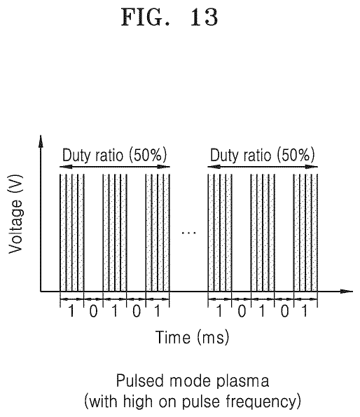

FIG. 13 is a diagram schematically showing a pulse plasma with a relatively high ON pulse frequency used in a PECVD process. Referring to FIG. 13, an example of a pulsed mode plasma method, unlike the continuous plasma method of FIG. 12, is shown.

The pulsed mode plasma method is a method, as described above, in which a pulse wave of the RF power is formed by pulsing the RF power applied to the plasma source or a bias electrode in a plasma reaction device, and accordingly, pulsed plasma is formed in the reaction space. According to the pulsed mode plasma method, plasma generation and destruction are repeatedly performed by adjusting on-period and off-period of the plasma, and thus, the plasma characteristics may be precisely controlled to be suitable for the processes according to the characteristics of the process.

Referring to FIG. 13, FIG. 13 is provided to describe the pulsed plasma having a relatively high ON pulse frequency, and section ‘1’ denotes a section in which the RF power is turned on (ON) and section ‘0’ denotes a section in which the RF power is turned off (OFF). Also, in FIG. 13, it may be set that one ON-section (that is, section ‘1’) may have a ON pulse frequency of about 4 kHz to about 10 KHz, for example, about 5 kHz.

In the substrate processing method according to one or more embodiments of the present disclosure, an arbitrary reference ON pulse frequency may be set as 4 kHz in the gap-fill process of the flowable film by the PECVD process. The reference ON pulse frequency may vary depending on processing conditions (e.g., may be greater or less than 4 kHz). The above ON pulse frequency of 5 kHz may be an execution ON pulse frequency and may be greater than the reference ON pulse frequency.

In addition, in FIG. 13, the duty ratio is set as 50%. The duty ratio represents an operating ratio of the pulsed plasma, and refers to a ratio of a first time in the ON-section of the pulse plasma with respect to the first time in the ON-section and a second time in an OFF-section of the pulsed plasma. Therefore, for example, the duty ratio of 50% denotes that, when one period of the pulse is 100%, the ON-section of the pulsed plasma is 50% and the OFF-section is 50%. In another example, the duty ratio of 30% denotes that, when one period of the pulse is 100%, the ON-section of the pulsed plasma is 30% and the OFF-section is 70%.

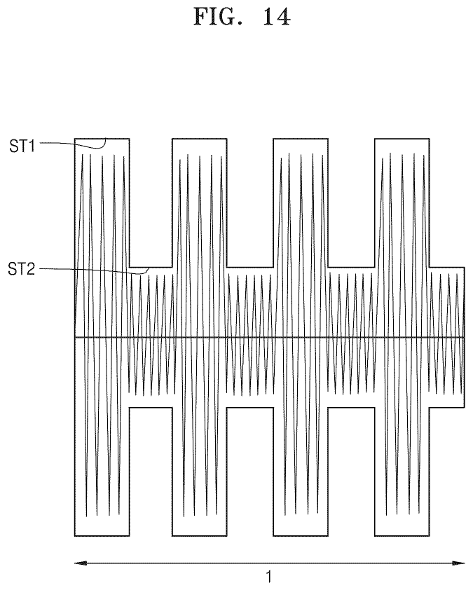

FIG. 14 is an enlarged view illustrating a section ‘1’ of FIG. 13, that is, a section in which the RF power is turned on (ON). As shown in FIG. 14, in the section in which the RF power is turned on (ON), the pulsed plasma having the high ON pulse frequency of 5 KHz is applied. The voltage of the pulsed plasma has a first state ST1 and a second state ST2, and during the ON-section, the first state ST1 and the second state ST2 are repeated with a certain period. In an embodiment in which the pulsed frequency is about 4 kHz to about 10 KHz, the period may be 0.1 ms to about 0.25 ms. In an embodiment of the high ON pulse frequency of 5 kHz, the period may be about 0.2 ms.

In one or more embodiments, as shown in FIG. 14, the first state ST1 and the second state ST2 of the pulsed plasma may be signals of different levels (e.g., voltages) having the same vibration frequency (e.g., RF frequency). In another example, the first state ST1 and the second state ST2 of the pulsed plasma may be signals of different levels having different frequencies. In more detail, the first state ST1 of the pulsed plasma may have the RF frequency and the second state ST2 of the pulsed plasma may be maintained at a ground level. In other words, at least the first state of the pulsed plasma may have a vibration frequency greater than that of the second state. Also, the frequency of the signal vibrating during at least one state of the pulsed plasma is in MHz unit, whereas the ON pulse frequency of the pulsed plasma including the first state (that is, the pulsed plasma which is repeated in the first state and the second state) may be in kHz unit. Therefore, the vibration frequency of at least first state of the pulsed plasma may be greater than the ON pulse frequency of the pulsed plasma.

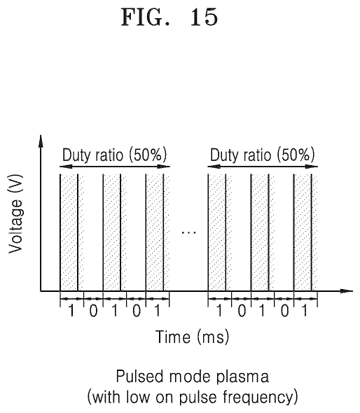

FIG. 15 is a diagram schematically showing a pulse plasma with a relatively low ON pulse frequency used in a PECVD process. FIG. 15 is a diagram for illustrating another example of the pulsed mode plasma method.

Referring to FIG. 15, FIG. 15 is provided to describe the pulsed plasma having a relatively low ON pulse frequency, and section ‘1’ denotes a section in which the RF power is turned on (ON) and section ‘0’ denotes a section in which the RF power is turned off (OFF). Also, in FIG. 15, one ON-section (that is, section ‘1’) may have the ON pulse frequency of about 0.5 KHz to about 4 KHz, and in order to clarify the comparison with the high ON pulse frequency of FIG. 13, for example, the ON-section may be set to have the ON pulse frequency of about 2 KHz.

In addition, in FIG. 15, the duty ratio is set as 50%. As described above, the duty ratio of 50% denotes that, when one period of the pulse is 100%, the ON-section of the pulsed plasma is 50% and the OFF-section is 50%. When comparing FIG. 13 with FIG. 15, in both FIGS. 13 and 15, the duty ratio is set as 50%, and FIGS. 13 and 15 are different in that the pulse frequencies of the pulsed plasma are different, that is, about 5 KHz and about 2 KHz.

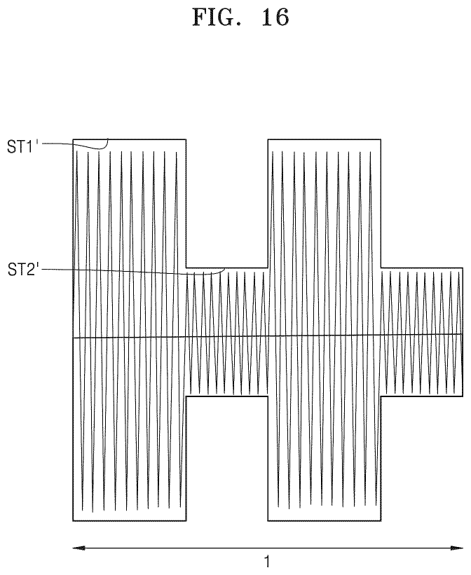

FIG. 16 is an enlarged view illustrating the section ‘1’ of FIG. 15, that is, a section in which RF power is turned on (ON). As shown in FIG. 16, during the section in which the RF power is turned on (ON), the pulsed plasma having a low ON pulse frequency of 2 kHz is applied. The voltage of the pulsed plasma has a first state ST1′ and a second state ST2′, and during the ON-section, the first state ST1′ and the second state ST2′ are repeated with a certain period. In an embodiment of the low ON pulse frequency of 2 kHz, the period may be about 0.5 ms.

In one or more embodiments, as shown in FIG. 16, the first state ST1′ and the second state ST2′ of the pulsed plasma may be signals of different levels (e.g., voltages) having the same vibration frequency (e.g., RF frequency). In another example, the first state ST1′ and the second state ST2′ of the pulsed plasma may be signals of different levels having different frequencies. In more detail, the first state ST1′ of the pulsed plasma may have the RF frequency and the second state ST2′ of the pulsed plasma may be maintained at a ground level. In other words, at least the first state of the pulsed plasma may have a vibration frequency greater than that of the second state. Also, the vibration frequency of at least first state of the pulsed plasma may be greater than the ON pulse frequency of the pulsed plasma.

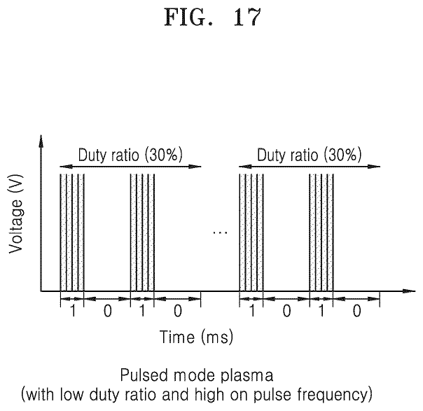

FIG. 17 is a schematic diagram for describing a pulse plasma method having a relatively low duty ratio and a high ON pulse frequency used in a PECVD process. When comparing FIG. 17 with FIG. 13, the duty ratio is reduced from 50% to 30%, and the ON pulse frequency is, for example, 5 KHz which is the same as the ON pulse frequency in FIGS. 13 and 14.

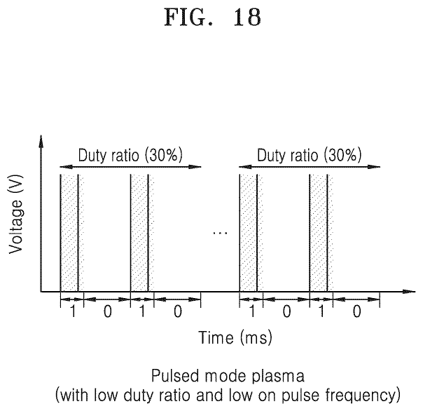

FIG. 18 is a schematic diagram for describing a pulsed mode plasma method having a relatively low duty ratio and a low ON pulse frequency used in a PECVD process. When comparing FIG. 18 with FIG. 15, the duty ratio is reduced from 50% to 30%, and the ON pulse frequency is, for example, 2 KHz which is the same as the ON pulse frequency in FIGS. 15 and 16.

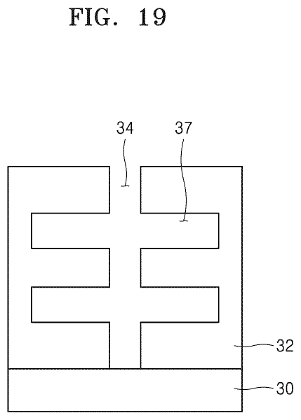

FIGS. 19 to 23 are cross-sectional views for describing a substrate processing method according to an embodiment of the present disclosure in a processing order.

Referring to FIG. 19, a substrate provided in a reaction space (not shown) in which a gap-fill process may be performed is shown. A gap structure may be formed in a partial area of a surface of a substrate 30 or a partial area of a surface of a material layer 32 on the substrate 30, wherein the gap structure may include a first recess 34 having a certain depth in the vertical direction and a certain width in the horizontal direction and second recesses 37 each extending from the first recess in a different direction (e.g., horizontal direction) from the vertical direction.

In one or more embodiments, the first recess 34 may have a width of 20 nm or less in the horizontal direction. In one or more embodiments, when the second recess 37 is formed to extend in the horizontal direction, the second recess 37 may have the width of 20 nm or less in the vertical direction. The substrate may include a semiconductor material such as Si or Ge, or various compound semiconductor materials such as SiGe, SiC, GaAs, InAs, and InP, and may include various substrates used in a semiconductor apparatus such as a silicon on insulator (SOI), silicon on sapphire (SOS), etc., a display apparatus, etc.

The first recess 34 and the second recess 37 may include various shapes of recess regions formed in the surface of the substrate 30, as well as an STI that is generally used to define an active area during the semiconductor manufacturing processes. In one or more embodiments, the first recess 34 and the second recess 37 may be used in a structure in which a lateral pattern and a trench pattern are mixed, such as a gate all around (GAA) structure. In an additional embodiment, the first recess 34 and the second recess 37 may be used to form elements of a vertical type NAND device.

In one or more embodiments, the first recess 34 and the second recess 37 may be provided in the form of vias that penetrate through a conductive layer located between insulating layers or an insulating layer located between conductive layers. In FIG. 19, the first recess 34 and the second recess 37 are obtained by etching and removing some parts in the material layer 32 formed on the surface of the substrate 30. The material layer 32 may include, for example, a conductive material, an insulating material, or a semiconductor material.

Also, the material layer 32 may be shown as a single layer, but may have multiple layers. Also, each of the first recess 34 and the second recess 37 may have a cylindrical shape, but a cross-sectional shape of a surface of each of the first recess 34 and the second recess 37 may have an elliptical shape and a various polygonal shapes such as a triangular shape, a rectangular shape, a pentagonal shape, etc. Also, the first recess 34 and the second recess 37 may be provided as island shapes having various surface cross-sectional shapes, but the first and second recesses 34 and 37 may have line shapes on the substrate 30.

In one or more embodiments, the first recess 34 may have a vertical-type profile having a roughly consistent width from the upper portion (e.g., entrance region of the first recess 34) to the lower portion, but may have a non-vertical type profile having a width that is reduced or increased linearly or in stepped shape from the upper portion to the lower portion, or the width in a part of the gap greater than or less than the width at the upper portion of the gap.

In an alternative embodiment, the second recess 37 may have a horizontal-type profile having a roughly consistent width from the entrance region (e.g., a region adjacent to the first recess 34) to an end region, but may have a non-horizontal type profile having a width that is reduced or increased linearly or in stepped shape from the entrance region to the end region, or the width in a part of the second recess 37 greater than or less than the width at the entrance region of the second recess 37.

In addition, FIG. 19 shows the gap structure in which the material layer 32 having a different material from that of the substrate 30 is on the substrate 30, but in one or more embodiments, the gap structure may be formed in the substrate itself. Therefore, in the present specification, the substrate may refer to the substrate 30 only, or may refer to a substrate having various surface structures before the flowable film according to the present disclosure, e.g., the flowable silicon nitride film, is formed thereon.

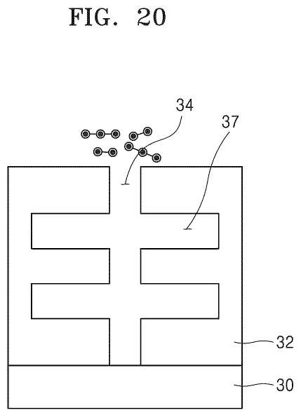

Referring to FIG. 20, at least one gas is supplied onto the substrate 30 on which the gap structure may be formed in the reaction space in which the gap-fill process may be performed. In one or more embodiments, the at least one gas may include a source having flowability and a reactant having reactivity with the source. For example, a silicon precursor and a nitrogen-containing gas may be supplied in order to perform a silicon nitride gap-fill process.

FIG. 20 shows an oligomerization process of the silicon precursor source with the supply of the silicon precursor and the nitrogen-containing gas. The silicon precursor used in one or more embodiments of the present disclosure may have a molecular structure that is not too simple or not too complicated, for example, an oligomer silicon precursor source having about two to about ten chain structures. Examples of oligomer silicon sources may include dimer-trisilylamine (TSA), trimer-TSA, tetramer-TSA, pentamer-TSA, hexamer-TSA, heptamer-TSA, octamer-TSA, etc.

In some embodiments, each of the oligomer silicon sources may be supplied solely to the reaction space, for example, dimer-TSA may be supplied solely as a silicon precursor source, and in another embodiment, trimmer-TSA may be supplied solely as a silicon precursor source. Also, in one or more embodiments, two or more kinds of silicon precursor sources may be supplied along with each other. In one or more embodiments, dimer-TSA and trimmer-TSA may be simultaneously supplied as the silicon precursor source, in one or more other embodiments, trimer-TSA and tetramer-TSA may be simultaneously supplied as the silicon precursor source, and in one or more other embodiments, dimer-TSA, trimmer-TSA, and tetramer-TSA may be simultaneously supplied as the silicon precursor source.

FIG. 20 shows that, for example, dimer-TSA and trimmer-TSA are simultaneously supplied as the silicon precursor source. In addition, an oligomer silicon precursor source that is synthesized in advance to have about two to about ten chain structures may be supplied into the reaction space, and the oligomer silicon precursor source having less chain structures may be formed to be a structure having about ten chain structures through the oligomerization and the condensation while flowing on an exposed surface of the substrate.

In addition, the nitrogen-containing gas used in one or more embodiments of the present disclosure may use at least one selected from N₂, N₂O, NO₂, NH₃, N₂H₂, N₂H₄, radicals thereof, or a mixture thereof. In an embodiment, NH₃ may be used as the nitrogen-containing gas.

In addition, a temperature of the substrate in the reaction space may be maintained at, for example, about 100° C. or less, for example, about 30° C. to about 70° C. A processing temperature in the reaction space or, a temperature of a container of the silicon precursor source, and a temperature of silicon precursor source transfer line may be maintained at about 100° C. or less, for example, about 30° C. to about 70° C. In addition, a radio frequency (RF) power of about 100 W to about 500 W, for example, about 200 W to about 400 W, is applied to the reaction space to make a plasma environment in the reaction space.

The RF power recited herein may denote a total power supplied for a certain time based on the duty ratio of 100%, and when the duty ratio is reduced, the certain time may increase in order to increase the RF power of the same magnitude. The RF power with the reduced duty ratio and increased application time is referred to as RF plasma. The RF used in the RF plasma may be about 13 MHz to about 60 MHZ, for example, about 20 MHz to about 30 MHz.

In order to make the plasma atmosphere in the reaction space, according to one or more embodiments of the present disclosure, an in-situ direct plasma treatment in which the RF power or the RF plasma is directly applied to the reaction space while supplying the silicon precursor source and the nitrogen-containing gas along with each other into the reaction space so that the plasma is generated on the substrate may be performed. To do this, in one or more embodiments, a voltage is applied to an electrode arranged in the reaction space to form a pulsed plasma atmosphere.

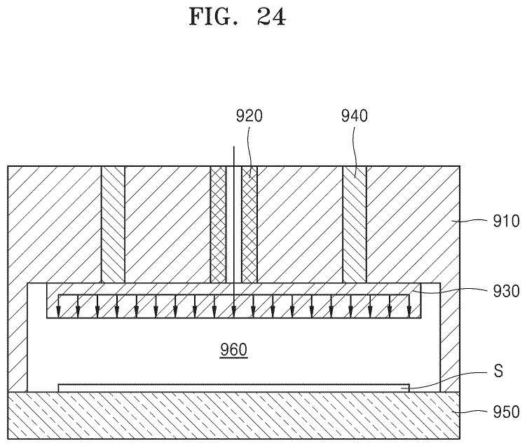

In an additional embodiment, the electrode arranged in the reaction space for the in-situ direct plasma treatment may be at least one of a gas supply unit configured to supply at least one gas and a substrate support unit configured to support the substrate. An example of the substrate processing apparatus in which the gas supply unit and/or the substrate support unit functions as the electrode is shown in FIG. 24, and the substrate processing apparatus will be described later in more detail.

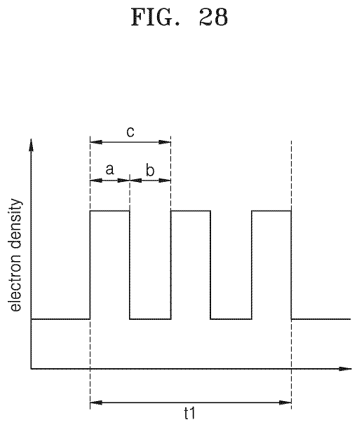

The plasma power (e.g., RF plasma) directly applied to the reaction space may be adjusted to have the duty ratio of 50% or less. As shown in FIG. 28, the plasma duty ratio is denoted by a ratio of RF ON-time (a) with respect to a unit period (a+b) of the RF pulse. That is, the duty ratio is defined as a/(a+b) or a/c in FIG. 28. When the RF ON-time (a) is short or RF OFF-time (b) is long, the plasma duty ratio is reduced, and when the RF ON-time (a) is long or the RF OFF-time (b) is short, the plasma duty ratio is increased.

During the RF ON-operation of the RF pulse, the RF pulse having the ON pulse frequency may be applied. In one or more embodiments, the ON pulse frequency may be in a range of 4 kHz to 6 kHz. In more detail, as shown in FIG. 13, the RF pulse having the ON pulse frequency of 5 kHz may be applied. Also, a frequency of the RF voltage in the RF pulse may be about 10 MHz or greater. In detail, as shown in FIG. 14, the frequency of the RF voltage used in the RF pulse is about 13 MHz to about 60 MHZ, for example, about 20 MHz to about 30 MHz.

According to the embodiments of the present disclosure, the duty ratio of the plasma is adjusted to be 50% or less. Therefore, the voltage applied to the electrode arranged in the reaction space is applied for a first time (that is, RF ON-time), and the applying of the voltage may be suspended during a second time (that is, RF OFF-time) that is equal to or greater than the first time. As described, by adjusting the duty ratio of the pulsed plasma, the generation of pores at the end portions of the first recess 34 and the second recess 37 may be suppressed.

In particular, according to the embodiments of the present disclosure, the generation of pores due to the capillary condensation at the end portion of the second recess extending in the horizontal direction may be suppressed. In detail, when the duty ratio of the pulsed plasma is adjusted as 50% or less (for example, between 20% to 40%), the deposition rate of the flowable film is reduced, and a chemical reaction occurs during the RF ON-time (a) and the flowability of the film may decrease. The film having the reduced flowability may prevent the capillary condensation. Consequently, the capillary condensation effect occurring in the second recess may be suppressed while filling the second recess 37 extending in the horizontal direction, and thus, the generation of pore at the end of the second recess 37 may be decreased.

Additionally, in an alternative embodiment, the plasma power (e.g., RF plasma) directly applied to the reaction space may be in the form of pulsed plasma. In other words, under the plasma atmosphere, the first recess 34 and the second recess 37 may be filled with the flowable film. The pulsed plasma may have an arbitrary reference ON pulse frequency, and in one or more embodiments, the reference ON pulse frequency may be about 4 kHz. In this case, pulsed plasma having an execution ON pulse frequency greater than 4 kHz (e.g., 4 kHz to 10 KHz, for example, 4 kHz to 6 kHz) may be supplied.

The generation of pores at the end portion of the second recess may be further suppressed by adjusting the ON pulse frequency of the pulsed plasma. The present inventor identified that it is effective to increase the ON pulse frequency of the pulsed plasma in improving the capillary condensation that affects the gap-fill in the lateral direction structure. To this end, a step in which a reference ON pulse frequency (e.g., 4 kHz) that becomes an arbitrary reference of the pulsed plasma is set and the execution ON pulse frequency (e.g., 5 kHz) that is greater than the reference ON pulse frequency is set may be performed. The generation of pores at the end of the second recess 37 may be suppressed while supplying the pulsed plasma having the execution ON pulse frequency.

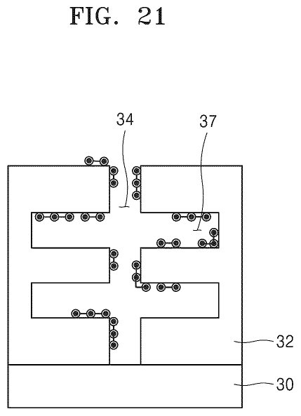

Referring to FIG. 21, a process of generating the oligomerization and the condensation among molecules of the silicon precursor source supplied into the reaction space is shown. That is, the oligomer silicon precursor supplied into the reaction space along with the nitrogen-containing gas that is a reactant flows with flowability on the exposed surface of the substrate due to the heat energy supplied onto the substrate via the heating block, on which the substrate is mounted, in the plasma atmosphere reaction space, and while the oligomer silicon precursor source flows on the substrate, the molecules of the oligomer precursor source may be bonded. In addition, the structure having about ten chain structures may be formed through the oligomerization and the condensation.

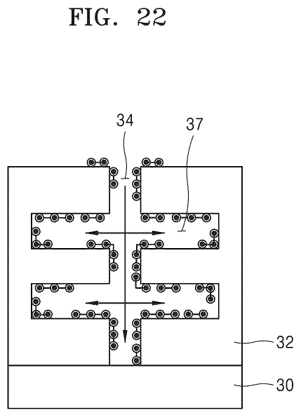

Referring to FIG. 22, the oligomers having flowability flow toward the lower region of the first recess 34 due to the gravity along the exposed surface of the substrate 30 on which the first recess 34 is formed. Also, the oligomers having the flowability may flow toward the end region of the second recess 37 due to the capillary effect and the gravity along the exposed surface of the entrance region (e.g., the region adjacent to the first recess 34) of the second recess 37, which is adjacent to the first recess 34. When the gap is filled by the oligomers having the flowability, the gap may be filled without generating a void or a seam.

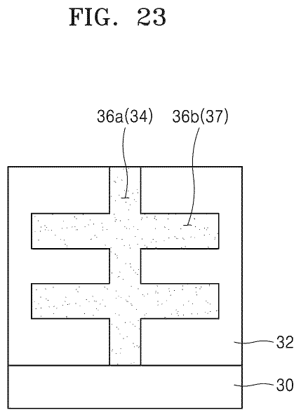

Referring to FIG. 23, the oligomers having the flowability continuously move toward the lower region of the first recess 34 along the exposed surface of the first recess 34, and thus, a silicon nitride film 36a may partially fill the first recess 34 in a bottom-up manner from the lower region of the first recess 34. Also, the oligomers having the flowability continuously move toward the end portion of the second recess 37 along the entrance region of the second recess 37, and thus, a silicon nitride film 36b may partially fill the second recess 37 from the entrance region of the second recess 37.

Here, the silicon nitride films 36a and 36b filling the first recess 34 and the second recess 37 may have the cross-linking structure of a circular loop shape due to the cross-linking, as shown in FIG. 11. The silicon nitride film 36a filling the first recess 34 formed in FIG. 23 is defined as a first silicon nitride film, and the silicon nitride film 36b filling the second recess 37 is defined as a second silicon nitride film.

As a post-process, the post-treatment may be performed in the first recess 34 and the second recess 37, and the surface may be planarized through, for example, an etch-back process so that the upper surface of the material layer 32 may be exposed. The post-treatment may include, for example, a process of densifying the first and second silicon nitride films 36a and 36b. In another example, the post-treatment may include a process of transforming the first and second silicon nitride films 36a and 36b into silicon oxide films. In one or more embodiments, the transformation process may be performed by a remote plasma application method. Moreover, the post-treatment may further include a process of densifying the silicon oxide films.

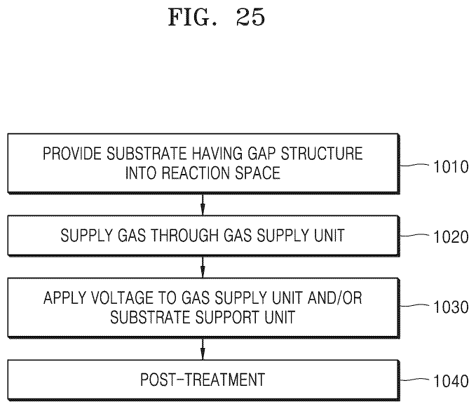

FIG. 24 is a diagram schematically showing a substrate processing apparatus according to an embodiment of the present disclosure, and FIG. 25 is a flowchart schematically illustrating a substrate processing method by using the substrate processing apparatus. The substrate processing methods according to one or more embodiments may be modified examples of the substrate processing method according to above-described embodiments. Hereinafter, descriptions about the elements described above will be omitted.

Referring to FIG. 24, the substrate processing apparatus may include a reactor wall 910, a conduit 920, a gas supply unit 930, an RF rod 940, and a substrate support unit 950. Examples of the substrate processing apparatus described with reference to the present embodiment may include a semiconductor or display substrate deposition apparatus, but are not limited thereto.

The reactor wall 910 may be an element of a reactor. In other words, a reaction space 960 for processing the substrate (e.g., gap-fill) may be formed by the reactor wall structure. For example, the reactor wall 910 may include at least one through-hole. A gas supply channel may be provided via the through-hole of the reactor wall 910.

The conduit 920 may be arranged in the reactor wall 910 via the through-hole. The conduit 920 may be a gas supply channel of the substrate processing apparatus. When a deposition apparatus is an atomic layer deposition (ALD) apparatus, a source gas, a purge gas, and/or a reactant gas may be supplied through the conduit 920. The conduit 920 may include an insulating material. In an alternative embodiment, the conduit 920 may be an insulating conduit formed of an insulating material.

The gas supply unit 930 may be connected to the conduit 920 that may be a gas supply channel. The gas supply unit 930 may be fixed on the reactor. For example, the gas supply unit 930 may be fixed to the reactor wall 910 via a fixing member (not shown). The gas supply unit 930 may be configured to supply a gas onto a substrate S in the reaction space 960. For example, the gas supply unit 930 may include a shower head assembly that is configured to evenly spray the gas.

The RF rod 940 may be connected to the gas supply unit 930 after passing through at least a part of the reactor wall 910. The RF rod 940 may be connected to a power generation unit (not shown) on the outside. FIG. 24 shows two RF rods 940, but one or more embodiments are not limited thereto, that is, two or more RF rods may be installed to improve uniformity in the distribution of the RF power supplied to the reaction space 960. Also, although not shown in the drawings, an insulator may be arranged between the RF rod 940 and the reactor wall 910 in order to block the electrical connection between the RF rod 940 and the reactor wall 910.

The gas supply unit 930 may be a conductor and may be used as an electrode for generating plasma. That is, the gas supply unit 930 is connected to the RF rod 940, and thus, the gas supply unit 930 may function as one electrode for generating the plasma. The gas supply unit 930 in the above type (the way of using the gas supply unit 930 itself as the electrode) will be referred to as a gas supply electrode, hereinafter.

The substrate support unit 950 may be configured to provide a region on which the substrate S such as the semiconductor or display substrate is mounted. Also, the substrate support unit 950 may be in contact with the lower surface of the reactor wall 910. For example, the substrate support unit 950 may be supported by the support (not shown) that may move up/down or rotate. The substrate support unit 950 is spaced apart from the reactor wall 910 or comes into contact with the reactor wall 910 due to the movement of the support, and then, the reaction space 960 may be opened or closed. Also, the substrate support unit 950 may be a conductor, and may be used as the electrode for generating plasma (that is, an opposite electrode of the gas supply electrode).

The direct plasma method refers to a method of generating plasma directly onto the substrate S in the reaction space by applying the RF power through the gas supply unit 930 and/or the substrate support unit 950 functioning as the electrode. FIG. 25 is a flowchart for illustrating the gap-fill process using the direct plasma method, which may be executed by using, for example, the substrate processing apparatus of FIG. 24.

Referring to FIG. 25, the substrate including the first recess extending in the vertical direction and the second recess extending in the horizontal direction is loaded onto the substrate support unit, and after that, the oligomer silicon precursor and the reactant gas may be supplied through the gas supply unit arranged on the substrate support unit. After or simultaneously with the supply of the gas through the gas supply unit, the voltage is applied to the gas supply unit and/or the substrate support unit to generate in-situ plasma in the reaction space.

As described above with reference to FIGS. 13 and 15, the process of generating the in-situ plasma may include the RF ON-operation carried out for first time and the RF OFF-operation carried out for second time that is greater than the first time. The in-situ plasma is generated after supplying the oligomer silicon precursor and the reactant gas, and thus, the gap-fill process in which the first recess and the second recess are filled with the flowable film may be performed. When the gap-fill process is finished, the post-treatment may be performed.

The step of the gap-fill process shown in FIG. 25 corresponds to the steps shown in FIG. 8. In detail, operation 1020 of supplying the gas via the gas supply unit of FIG. 25 may correspond to operation 120 of supplying the silicon precursor and the nitrogen-containing gas of FIG. 8. Also, operation 1030 of applying the voltage to the gas supply unit and/or the substrate support unit of FIG. 25 may correspond to operation 130 of filling the gap with the flowable silicon nitride film of FIG. 8. In addition, the post-treatment step 1040 of FIG. 25 may correspond to the post-treatment step 140 of FIG. 8. This denotes that the substrate processing apparatus of FIG. 24 may be manipulated according to the substrate processing method described with reference to FIG. 25 and then the substrate processing method according to the embodiment of FIG. 8 may be carried out.

When the gap-fill process with the flowable film is performed, the film has the flowability like the liquid, and thus, the fast gap-fill may be performed due to the capillary condensation in the narrower place. Due to the above issue, a thin film deposited in the narrow space may be affected by the subsequent plasma or may affect the gap-fill state of the continuous pattern. Therefore, adjusting of the capillary condensation rate becomes an important factor for adjusting the gap-fill state of the flowable film, and in a structure in which a transverse pattern and a longitudinal pattern are mixed such as the GAA structure, the capillary condensation is aimed to be adjusted by adjusting the duty plasma and the ON pulse frequency.

In general, in the GAA structure, the gap-fill process is carried out by CVD process by increasing a precursor vapor pressure or utilizing ALD process. In the process, the gap-fill process for the structure similar to the GAA is performed by utilizing the flowability process, and in order to suppress generation of micro-pores at the end portions of the horizontal recess and the vertical recess during the flowable film deposition process, the duty ratio and the ON pulse frequency of the RF plasma used when performing the flowable film deposition process are adjusted. As such, the capillary condensation effect in the narrow pattern region is delayed as much as possible to suppress the generation of micro-pores in the flowable film.

As shown in FIGS. 12 and 13, pulsed plasma (FIG. 13) having a duty ratio in contrast to the continuous plasma (FIG. 12) is divided into the plasma ON and OFF times, and the ON pulse frequency may be adjusted during the pulse ON-time to adjust the time for maintaining electrons, active species density, etc. in the plasma to a certain level. This can be utilized to further suppress or activate an active species-based chemical reaction.

In the present process, the process conditions need to be maintained so that the deposition rate of the flowable film degrades, which is essential for suppressing the capillary condensation effect, while the active species-based chemical reaction occurs dominantly. Therefore, the process conditions in which the duty ratio of the RF plasma is low and the ON pulse frequency is high is used. The low duty ratio has a relatively less plasma ON-time as compared with the high duty ratio, and thus, the chemical reaction relatively less occurs. In addition, when the ON pulse frequency is high, the period of generating a RF pulse is reduced, and thus, the chemical reaction is reduced and the active species-based chemical reaction increases. Thus, it is advantageous for the oligomeric synthesis which becomes a base of the flowable film.

Table 1 below schematically illustrate processing conditions of the substrate processing method according to one or more embodiments of the present disclosure.

TABLE 1

| Process Variable | Deposition Step |
|---|---|
| Time (sec) | 1-1800 |
| Pressure (Torr) | 1-10 |
| Process gas injection | ON |
| RF Power (W) | 50-1000 |
| Duty ratio (%) | 1-99 |
| ON Pulse Frequency (Hz) | 500-10000 |
| Temperature (° C.) | T < 150 |

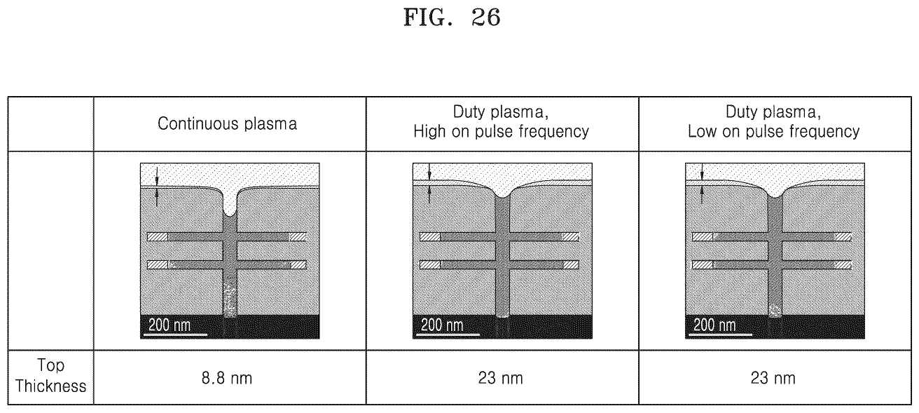

FIG. 26 shows gap-fill characteristics of a lateral structure pattern in a continuous plasma mode and according to a duty ratio and a ON pulse frequency in a duty plasma mode. As a thickness of an upper structure in the lateral direction increases, the flowable characteristic of the flowable film degrades. In addition, a thickness of the upper structure of the flowable film deposited in the duty plasma mode in the lateral direction (23 nm) is about three times greater than a thickness of the upper structure of the flowable film deposited in the continuous plasma mode in the lateral direction (8.8 nm).

When the deposition rate of the flowable film is high, the flowable film generally rapidly flows along the surface. However, when the deposition rate is low, the chemical reaction partially occurs during the plasma ON-time to suppress the flowability. In addition, under the duty plasma, the deposition seemed to be performed to be thicker due to the degradation in the flowability of the upper thin film due to the low deposition rate. As the flowable film is deposited thick on the upper portion, the rate of supplying the flowable film to the recess structure in the lateral direction decreases, and thus the capillary condensation effect is less shown.

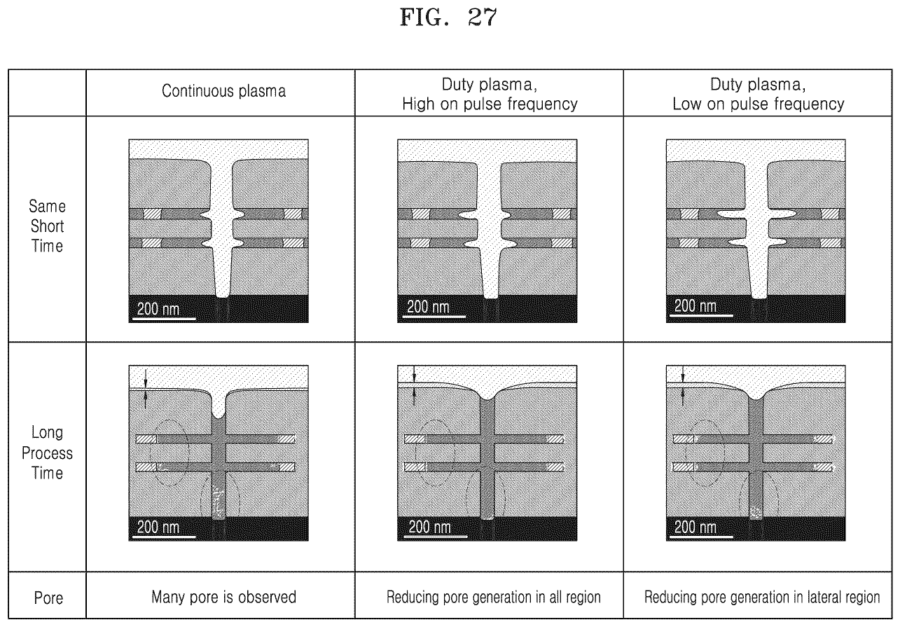

In FIG. 27, the gap-fill state was observed with shorter and longer process times as compared with FIG. 26 under the same condition. As a result of both cases of the duty plasma, it was identified that an amount of flowable film filling the gap in the lateral direction was reduced by about 50% to about 70% and the capillary condensation effect in the lateral recess was suppressed for an initial short time (e.g., 30 seconds to 40 seconds). When observing the patterns formed through a long processing time, in the continuous mode plasma, a lot of micro-pores were observed at the end portions of the recess in the horizontal direction and the recess in the vertical direction. However, under the duty plasma condition, the micro-pore was not observed in the flowable film formed at the end portion of the recess in the horizontal direction, and a few micro-pores were observed in the lower portion of the recess in the vertical recess with a low ON pulse frequency, and micro-pores were rarely shown with high ON pulse frequency. Thus, it was identified that the adjusting of the duty plasma and the ON pulse frequency is effective in improving the capillary condensation which affects the gap-fill in the lateral structure. In addition, in particular, at the end portion of the recess in the horizontal direction and the end portion of the recess in the vertical direction, film quality may be further improved with the high ON pulse frequency.

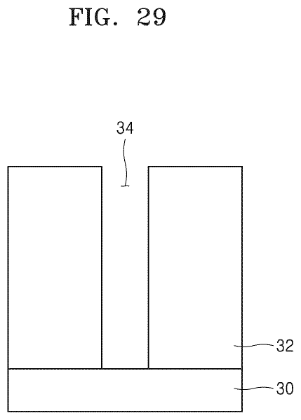

FIGS. 29 to 33 are cross-sectional views for describing a substrate processing method according to an embodiment of the present disclosure in a processing order.

Referring to FIG. 29, a substrate provided into a reaction space (not shown) in which a gap-fill process may be performed is shown. A gap structure may be formed in a partial area of a surface of a substrate 30 or a partial area of a surface of a material layer 32 on the substrate 30, wherein the gap structure may include a recess 34 having a certain depth in the vertical direction and a certain width in the horizontal direction.

In one or more embodiments, the recess 34 may have a width of 20 nm or less in the horizontal direction. In one or more embodiments, the recess 34 may have an aspect ratio of 1:10 or greater. For example, when the recess 34 has a width of 20 nm in the horizontal direction, the recess 34 may have a depth of 200 nm or greater. In an alternative embodiment, the recess 34 may have an aspect ratio of 1:20 or greater.

The substrate may include a semiconductor material such as Si or Ge, or various compound semiconductor materials such as SiGe, SiC, GaAs, InAs, and InP, and may include various substrates such as a silicon on insulator (SOI), silicon on sapphire (SOS), etc., used in a semiconductor device or a display device, etc.

The recess 34 may include various shapes of recess region formed in the surface of the substrate 30, as well as an STI that is generally used to define an active area in the semiconductor manufacturing processes. In some embodiments, the recess 34 may be used to form an element of a vertical-type NAND device. In one or more embodiments, the recess 34 may be provided in the form of a via that penetrates through a conductive layer located between insulating layers or an insulating layer located between conductive layers.

The recess 34 in FIG. 29 shows that the recess 34 is formed by etching and removing a part from the material layer 32 formed on the surface of the substrate 30. The material layer 32 may include, for example, a conductive material, an insulating material, or a semiconductor material.

Also, the material layer 32 may be shown as a single layer, but may have multiple layers. In addition, each recess 34 may have a cylindrical shape, but a cross-sectional shape on the surface of the recess 34 may have an elliptical shape, or various polygonal shapes such as triangular shape, rectangular shape, pentagonal shape, etc., as well as the circular shape. Also, the recess 34 may have an island shape having various surface cross-sectional shapes, but the recess 34 may be formed in a line shape on the substrate 20.

In one or more embodiments, the recess 34 may have a vertical-type profile having a roughly consistent width from the upper portion (e.g., entrance region of the recess 34) to the lower portion, but may have a non-vertical type profile having a width that is reduced or increased linearly or in stepped shape from the upper portion to the lower portion, or the width in a part of the gap may be greater than or less than the width at the upper portion of the gap.

In addition, FIG. 29 shows the gap structure in which the material layer 32 having a different material from that of the substrate 30 is on the substrate 30, but in one or more embodiments, the gap structure may be formed in the substrate itself. Therefore, in the present specification, the substrate may refer to the substrate 30 only, or may refer to a substrate having various surface structures before the flowable film according to the present disclosure, e.g., the flowable silicon nitride film, is formed thereon.

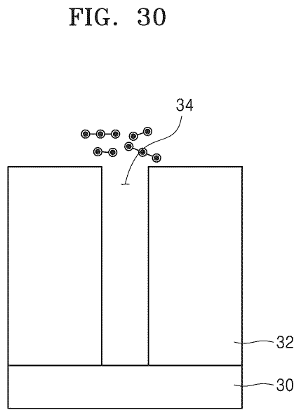

Referring to FIG. 30, at least one gas is supplied onto the substrate 30 on which the gap structure may be formed in the reaction space in which the gap-fill process may be performed. In one or more embodiments, the at least one gas may include a source having flowability and a reactant having reactivity with the source. For example, a silicon precursor and a nitrogen-containing gas may be supplied in order to perform a silicon nitride gap-fill process.

FIG. 30 shows an oligomerization process of the silicon precursor source with the supply of the silicon precursor and the nitrogen-containing gas. The silicon precursor used in one or more embodiments of the present disclosure may have a molecular structure that is not too simple or not too complicated, for example, an oligomer silicon precursor source having about two to about ten chain structures. Examples of oligomer silicon sources may include dimer-trisilylamine (TSA), trimer-TSA, tetramer-TSA, pentamer-TSA, hexamer-TSA, heptamer-TSA, octamer-TSA, etc.

In some embodiments, each of the oligomer silicon sources may be supplied solely to the reaction space, for example, dimer-TSA may be supplied solely as a silicon precursor source, and in another embodiment, trimmer-TSA may be supplied solely as a silicon precursor source. Also, in one or more embodiments, two or more kinds of silicon precursor sources may be supplied along with each other. In one or more embodiments, dimer-TSA and trimmer-TSA may be simultaneously supplied as the silicon precursor source, in one or more other embodiments, trimer-TSA and tetramer-TSA may be simultaneously supplied as the silicon precursor source, and in one or more other embodiments, dimer-TSA, trimmer-TSA, and tetramer-TSA may be simultaneously supplied as the silicon precursor source.

FIG. 30 shows that, for example, dimer-TSA and trimmer-TSA are simultaneously supplied as the silicon precursor source. In addition, an oligomer silicon precursor source that is synthesized in advance to have about two to about ten chain structures may be supplied into the reaction space, and the oligomer silicon precursor source having less chain structures may be formed to have a structure having about ten chain structures through the oligomerization and the condensation while flowing on an exposed surface of the substrate.

In addition, the nitrogen-containing gas used in one or more embodiments of the present disclosure may use at least one selected from N₂, N₂O, NO₂, NH₃, N₂H₂, N₂H₄, radicals thereof, and a mixture thereof. In an embodiment, NH₃ may be used as the nitrogen-containing gas.

In addition, a temperature of the substrate in the reaction space may be maintained at, for example, about 100° C. or less, for example, about 30° C. to about 70° C. A processing temperature in the reaction space or, a temperature of a container of the silicon precursor source, and a temperature of silicon precursor source transfer line may be maintained at about 100° C. or less, for example, about 30° C. to about 70° C. In addition, a radio frequency (RF) power of about 100 W to about 500 W, for example, about 200 W to about 400 W, is applied to the reaction space to make a plasma environment in the reaction space.

The RF power recited herein may denote a total power supplied for a certain period of time based on the duty ratio of 100%, and when the duty ratio is reduced, the certain period of time may increase in order to increase the RF power of the same magnitude. The RF power with the reduced duty ratio and increased application time is referred to as RF plasma. The RF frequency used in the RF plasma may be about 13 MHz to about 60 MHz, for example, about 20 MHz to about 30 MHz.

In order to make the plasma atmosphere in the reaction space, according to one or more embodiments of the present disclosure, an in-situ direct plasma treatment in which the RF power or the RF plasma is directly applied to the reaction space while supplying the silicon precursor source and the nitrogen-containing gas along with each other into the reaction space so that the plasma is generated on the substrate may be performed. To do this, in one or more embodiments, a voltage is applied to an electrode arranged in the reaction space to form a pulsed plasma atmosphere.

During the RF ON-operation of the RF pulse, the RF pulse having the ON pulse frequency may be applied. In one or more embodiments, the ON pulse frequency may be in a range of 500 Hz to 2 kHz. In more detail, the RF pulse having the ON pulse frequency of 2 kHz may be applied. Also, a frequency of the RF voltage in the RF pulse may be about 10 MHz or greater. In detail, the frequency of the RF voltage used in the RF pulse is about 13 MHz to about 60 MHz, for example, about 20 MHz to about 30 MHz.

According to the embodiments of the present disclosure, the duty ratio of the plasma is adjusted to be 50% or less. In one or more embodiments, the duty ratio of plasma may be set within a range of 20% to 40%. Due to the duty ratio of 50% or less, the voltage applied to the electrode arranged in the reaction space is applied for a first time (that is, RF ON-time), and the applying of the voltage may be suspended for a second time (that is, RF OFF-time) that is equal to or greater than the first time.

Generation of pores at the end portion of the recess 34 may be suppressed by adjusting the duty ratio of the pulsed plasma. In detail, when the applying of the plasma voltage is suspended during the RF OFF-time, from among radicals of a reactant, ions and electrons of the reactant generated by the applying of plasma, the ions and electrons may be removed and the radicals may only remain. Because the remaining radicals travel a relatively long distance, the radicals may move toward the bottom of the gap structure during the RF OFF-time. The radicals moved as described above may engage in the oligomerization reaction and condensation of the silicon precursor source molecules, and thus, a silicon nitride flowable film of relatively higher quality may be formed around the bottom of the gap structure.

As described above, according to the embodiments, the radicals of the reactant, the ions and electrons of the reactant are generated during the RF ON-time by adjusting the duty ratio of the plasma, and the ions and electrons are removed during the RF OFF-time so that the source and the radicals react with each other around the bottom of the gap structure. When the radical-based chemical reaction is prompted by the duty plasma, the silicon nitride film structure having high-quality cross-linking structure may be formed in the gap structure of HAR.

In some embodiments, the RF OFF-time (that is, the time of suspending the applying of plasma) may be proportional to the depth of the gap structure. This is to secure a sufficient time for the radicals to travel to the bottom of the gap structure, and the RF OFF-time may be proportional to the depth of the gap structure. Besides, a sufficient RF OFF-time may be secured so that the radical-based chemical reaction may be the main reaction for forming the silicon nitride film.

In more detail, a first reaction (that is, chemical reaction) may be performed for filling the gap structure during the RF ON-time in which the radicals of the reactant are generated, and a second reaction (radical-based chemical reaction) may be performed for filling the gap structure during the RF OFF-time in which the applying of plasma is suspended. In this case, the RF OFF-time may be increased by reducing the duty ratio of the duty plasma, and accordingly, the silicon nitride film may be formed by mainly using the radical-based chemical reaction. In this case, the film filling the gap includes a first part formed by the first reaction and a second part formed by the second reaction, and an amount of the second part may be greater than that of the first part.

Additionally, in an alternative embodiment, the plasma power (e.g., RF plasma) directly applied to the reaction space may be in the form of pulsed plasma. In other words, under the plasma atmosphere, the recess 34 may be filled with the flowable film. The pulsed plasma may have an arbitrary reference ON pulse frequency, and in one or more embodiments, the reference ON pulse frequency may be about 4 kHz. In this case, pulsed plasma having an execution ON pulse frequency less than 4 kHz (e.g., 500 Hz to 2 kHz) may be supplied.

The generation of pores at the end portion of the recess 34 may be further suppressed by adjusting the ON pulse frequency of the pulsed plasma. The present inventor identified that the pore generation may be suppressed effectively by reducing the ON pulse frequency of the pulsed plasma in the gap-fill process of the gap structure having HAR. To this end, a step in which a reference ON pulse frequency (e.g., 4 kHz) that becomes an arbitrary reference of the pulsed plasma is set and the execution ON pulse frequency (e.g., 2 kHz) that is less than the reference ON pulse frequency is set may be carried out. The generation of pores at the end of the recess 34 may be suppressed while supplying the pulsed plasma having the execution ON pulse frequency.

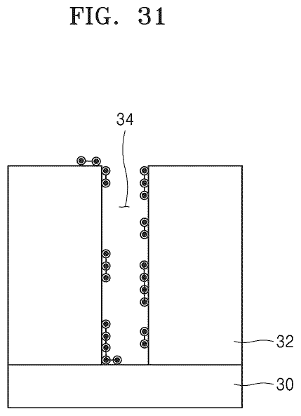

Referring to FIG. 31, a process of generating the oligomerization and the condensation among molecules of the silicon precursor source supplied into the reaction space is shown. That is, the oligomer silicon precursor supplied into the reaction space along with the nitrogen-containing gas that is a reactant, in the plasma atmosphere reaction space, flows with flowability on the exposed surface of the substrate due to the heat energy supplied onto the substrate via the heating block, on which the substrate is mounted. While the oligomer silicon precursor source flows on the substrate, the molecules of the oligomer precursor source may be bonded. In addition, the structure having about ten chain structures may be formed through the oligomerization and the condensation.

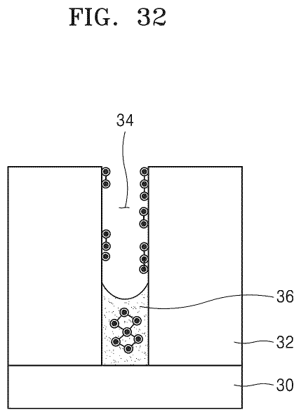

Referring to FIG. 32, the oligomers having flowability flow toward the lower region of the recess 34 due to the gravity along the exposed surface of the substrate 30 in which the recess 34 is formed. In particular, the oligomers flowing toward the lower region of the recess may continuously react with the radicals moving toward the bottom of the gap structure. As described above, when the gap is filled by the oligomers having flowability and the radicals moving toward the bottom of the gap structure, the gap may be filled while suppressing the generation of pores that may be generated at the end portion of the gap structure. A silicon nitride film 36 filled in the recess 34 may have a network structure of a circular loop shape due to the cross-linking.

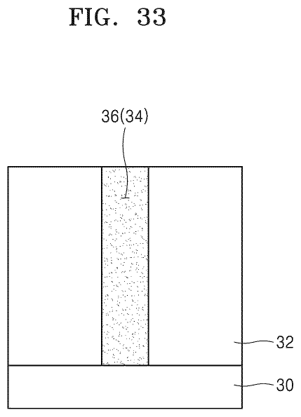

Referring to FIG. 33, the oligomers having the flowability continuously move toward the lower region of the recess 34 along the exposed surface of the recess 34, and thus, the silicon nitride film 36 may fill the recess 34 in a bottom-up manner from the lower region of the recess 34. As described above, in some embodiments, the silicon nitride film may include the first part formed by the chemical reaction and the second part formed by the radical-based chemical reaction. In this case, the amount of pores in the first part may be greater than that of the pores in the second part.

As a post-process, the post-treatment may be performed in the recess 34, and the surface may be planarized through, for example, an etch-back process so that the upper surface of the material layer 32 may be exposed. The post-treatment may include, for example, a process of densifying the silicon nitride film 36. In another example, the post-treatment may include a process of transforming the silicon nitride film 36 into a silicon oxide film. In one or more embodiments, the transformation process may be performed by a remote plasma application method. Moreover, the post-treatment may further include a process of densifying the silicon oxide films.

The above substrate processing method is distinguished from a flowable gap-fill process using remote plasma according to the related art in that the RF plasma atmosphere is directly formed in the reaction space and the gap structure is filled with the flowable film while supplying the gas. In other words, according to the disclosure, the radicals of the gas are generated directly in the reaction space by the in-situ plasma, by applying the voltage to the gas supply unit and/or the substrate support unit.

Moreover, according to one or more embodiments of the present disclosure, ions and/or electrodes, other than the radicals, are removed during the second time (RF-OFF section) that is equal to or greater than the first time (RF-ON section) by applying the duty plasma, and thus, other factors than the radicals (e.g., ions and/or electrons) may not be involved in the oligomerization in the bottom part of the gap.

Additionally, after the gap-fill process in the bottom part of the gap based on the radical-based chemical reaction, processes for carrying out the gap-fill on the other part (the part above the bottom of the gap) may be performed. For example, according to one or more embodiments of the present disclosure, the process of performing the gap-fill on the other part may be carried out based on a different plasma condition from that of the process of performing the gap-fill in the bottom part of the gap.

For example, in order to carry out the gap-fill in the bottom part of the gap, the plasma power may be applied during a first time, and the applying of the plasma power may be suspended during a second time that is equal to or greater than the first time. After that, in order to carry out the gap-fill with respect to the other parts of the gap, the plasma may be applied during a third period of time that is greater than the first time. The above additional plasma applying process may be carried out in the in-situ plasma type (that is, by applying the voltage to the gas supply unit and/or the substrate support unit).

Because the plasma power is applied during the third period of time that is greater than the first time in the additional plasma applying process, the gap-fill speed may increase. In other words, with respect to the bottom portion having high possibility of generating pores, the plasma having relatively less duty ratio is applied so that the generation of pores may be suppressed even with a longer time, and with respect to the other portion above the bottom portion, additional plasma having greater duty ratio is applied so that the gap-fill may be carried out rapidly. In one or more embodiments, the additional plasma may be applied in a continuous plasma method.

In order to carry out the gap-fill process with respect to an HAR gap structure according to the related art, a dep-etch-dep process, in which an ALD and an etching process are alternately performed, is used. To improve this, various processes such as a flowable film gap-fill, a spin-on dielectric process, etc. are being developed. In the present disclosure, when performing the flowable film gap-fill operation, a method for preventing generation of pores at the bottom part in the HAR structure is suggested.

When the gap-fill is carried out on the HAR pattern by using the flowable film deposition process according to the related art, pores may be generated in the flowable thin film deposited on the lower portion. Pores may be generated as polymers that are not properly polymerized are mixed. In order to suppress the generation of pores, it is important to adjust the RF plasma so that the radical-based chemical reaction may only occur. According to the disclosure, the duty plasma is adjusted and the ON pulse frequency is controlled so as to reduce the pores in the flowable film deposited in the bottom region of the HAR pattern.

As described above with reference to FIGS. 13 and 15, the continuous mode plasma is supplied with steady RF, but in the duty plasma, the plasma ON-OFF times are divided according to the duty ratio. In addition, the pulsed power may be applied during the ON-section of the duty plasma, and the number of times of repeating the pulsed type power application may be defined as the ON pulse frequency. In the present disclosure, the duty plasma and/or the ON pulse frequency is adjusted so that the radical-based chemical reaction may only occur in the plasma-OFF status, not the chemical reaction in the plasma-ON status, and thus, the oligomers of excellent quality may be generated, and the oligomers having the excellent quality may carry out the gap-fill in the bottom region of the HAR pattern so as to reduce generation of pores in the bottom region. In order to reduce the factors causing the chemical reaction, such as ions and electrons, while steadily maintaining the radicals, the RF plasma may be steadily turned on and off, and as the ON pulse frequency is lowered, the time in which the RF power is supplied and the RF power is not supplied during the ON-time of the duty plasma is increased simultaneously, and thus, the radical-based chemical reaction may become the main reaction.

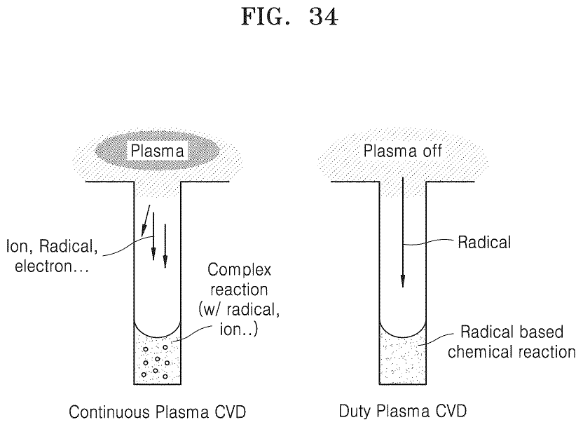

As shown in FIG. 34, in the continuous plasma chemical vapor deposition, the ions and electrons may enter inside the HAR pattern infrequently, which may affect the quality of flowable film on the lower region. However, in the duty plasma chemical vapor deposition, only radicals may be active during the plasma OFF-time and the travel distance of the radicals is longer, the radicals may only affect the thin film deposited on the lower region of the HAR pattern. This denotes that the factors rather than the radicals are not involved in the oligomerization in the bottom region.

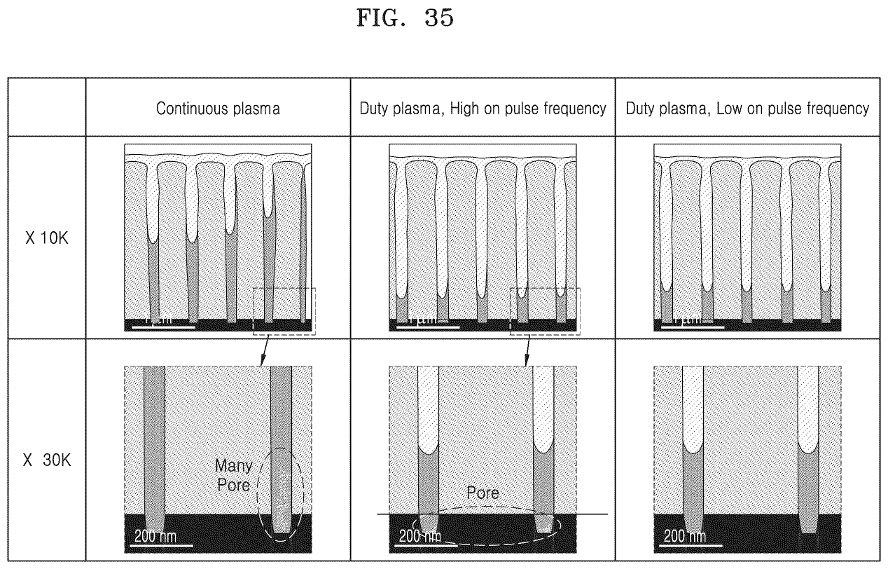

FIG. 35 shows a result of an experiment in which a flowable film is deposited on an HAR pattern by using continuous plasma and duty plasma. In case of the continuous plasma, the gap-fill was sufficiently performed, but pores were generated in the lower region. When the deposition is performed by using the duty plasma under the same condition, the radical-based chemical reaction only occurred, and thus, the gap-fill height was reduced due to decrease in the deposition speed, but the generation of pores was also reduced. When the low ON pulse frequency was applied in addition to the low duty ratio, the gap-fill height did not vary a lot, but the pores were not observed. This is because the radicals have to be generated while applying steadily the RF power with low ON pulse frequency even in the duty plasma environment, so as to sufficiently transfer the radicals to the lower portion of the HAR structure. The present inventor identified that the lower ON pulse frequency in the duty plasma environment was effective for suppressing the pore generation during gap-fill in the lower region of the HAR pattern.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing method comprising:
providing a substrate having a gap structure into a reaction space; and
supplying a silicon precursor and nitrogen reactant gas into the reaction space, and depositing a flowable silicon nitride film on the substrate to fill at least a part of the gap of the substrate, while maintaining an inside of the reaction space in a plasma state by applying radio frequency (RF) power in a pulsed mode,
wherein the RF power has a duty ratio of 50% or less.

2. The substrate processing method of claim 1, wherein the depositing of the silicon nitride film comprises generating a plasma by using direct plasma treatment of directly generating a plasma on the substrate by applying RF power into the reaction space while supplying the silicon precursor, the nitrogen reactant gas, and inert gas into the reaction space.

3. The substrate processing method of claim 1, wherein the silicon precursor is trimer-trisilylamine (TSA) or dimer-trisilylamine (TSA), and the nitrogen reactant gas is NH₃.

4. The substrate processing method of claim 1, wherein depositing the silicon nitride film comprises depositing the silicon nitride film by using a plasma enhanced chemical vapor deposition (PECVD) process.

5. A substrate processing method comprising:
providing a substrate having a gap structure into a reaction space;
supplying a silicon precursor and nitrogen reactant gas into the reaction space, and depositing a flowable silicon nitride film in a gap of the substrate while maintaining an inside of the reaction space in a plasma state by applying radio frequency (RF) power in a pulsed mode;
converting the flowable silicon nitride film into a silicon oxide film; and
forming a densified silicon oxide film by densifying the silicon oxide film,
wherein as a duty ratio of the RF power is 50% or less.

6. The substrate processing method of claim 5, wherein the applying of the RF power in the pulsed mode in the depositing causes generation of fewer micropores in the silicon nitride film in the gap, compared to a case where the RF power is continuously applied.

7. The substrate processing method of claim 5, wherein the conversion comprises converting the flowable silicon nitride film into the silicon oxide film by introducing remote oxygen (O₂) plasma to the flowable silicon nitride film.

8. The substrate processing method of claim 5, wherein the RF power has a frequency ranging from 13.56 MHz to 60 MHz.

9. The substrate processing method of claim 5, wherein a pulse frequency of the RF power ranges from 0 KHz to 100 KHz.

10. The substrate processing method of claim 5, wherein the deposition comprises depositing the flowable silicon nitride film by using a direct plasma treatment while supplying the silicon precursor, the nitrogen reactant gas, and inert gas into the reaction space.

11. The substrate processing method of claim 5, wherein the silicon precursor is at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂; dimer-trisilylamine, trimer-trisilylamine, tetramer-trisilylamine, pentamer-trisilylamine, hexamer-trisilylamine, heptamer-trisilylamine, octamer-trisilylamine, and a mixture thereof.

12. The substrate processing method of claim 5, wherein the nitrogen reactant gas is selected from at least one of NH₃, N₂, N₂O, NO₂, N₂H₂, N₂H₄, and a mixture thereof.

13. A method of filling a gap structure formed in a substrate with a flowable film, the method comprising:
supplying a source;
supplying a reactant having reactivity with the source;
generating radicals of at least the reactant by applying, for a first time, plasma via an electrode arranged in a reaction space; and
suspending, for a second time, the applying of the plasma, wherein the second time is greater than the first time.

14. The method of claim 13, wherein
the radicals travel toward a bottom of the gap structure during the suspending of the applying of the plasma.

15. The method of claim 14, wherein
the second time and a depth of the gap structure are proportional to each other.

16. The method of claim 13, wherein
during the generating of the radicals of the reactant, a first reaction for filling the gap structure occurs, and
during the suspending of the applying of the plasma, a second reaction for filling the gap structure occurs.

17. The method of claim 16, wherein
a film filling the gap by the method has a first part formed by the first reaction and a second part formed by the second reaction, and
an amount of the second part is greater than an amount of the first part.

18. The method of claim 13, further comprising
generating radicals of the reactant by applying additional plasma for a third period of time that is greater than the first time.

19. The method of claim 18, wherein
a duty ratio of the additional plasma is greater than a duty ratio of the plasma.

20. The method of claim 18, wherein
the additional plasma is applied in a continuous mode plasma method.
